(19) United States
(12) Patent Application Publication
(10) Pub. No.: US 2023/0420483 A1
(43) Pub. Date: Dec. 28, 2023

(54) ETCH PROTECTION AND QUANTUM MECHANICAL ISOLATION IN LIGHT EMITTING DIODES

(71) Applicant: Meta Platforms Technologies, LLC, Menlo Park, CA (US)

(72) Inventors: Yong Tae MOON, Plymouth (GB); Alexander TONKIKH, Wenzenbach (DE); Liang ZHANG, Singapore (SG); Shenghui LEI, Castleknock (IE); Ezzah Azimah BINTI ALIAS, Plymouth (GB); David MASSOUBRE, Rathcormac (IE); Christophe Antoine HURNI, Seattle, WA (US)

(21) Appl. No.: 18/461,424

(22) Filed: Sep. 5, 2023

Related U.S. Application Data
(60) Provisional application No. 63/412,874, filed on Oct. 3, 2022.

(51) Int. Cl. H01L 27/15

(52) U.S. Cl. CPC H01L 27/156

(57) ABSTRACT

Described are LED devices and corresponding manufacturing techniques. In some embodiments, an LED device includes a first doped semiconductor layer, a second doped semiconductor layer having an opposite doping, and a two-dimensional (2D) array of light emitting cells. Each light emitting cell corresponds to a mesa of an individual pixel and includes at least one quantum well. The 2D array is located between the first doped semiconductor layer and the second doped semiconductor layer. The LED device further includes a flattening layer between the first doped semiconductor layer and the 2D array. The flattening layer comprises an undoped quantum barrier (QB) layer that completely covers sidewalls of each light emitting cell in the 2D array. The undoped QB layer quantum mechanically isolates the light emitting cells from each other. The flattening or undoped QB layer may also protect the light emitting cells against etch-induced defects during a mesa pixelation process.

### CROSS-REFERENCE TO RELATED APPLICATIONS

This application claims the benefit and priority to U.S. Provisional Application No. 63/412,874, filed Oct. 3, 2022, entitled “ETCH PROTECTION AND QUANTUM MECHANICAL ISOLATION IN LIGHT EMITTING DIODES,” which is assigned to the assignee hereof and is herein incorporated by reference in its entirety for all purposes.

### BACKGROUND

Aspects of this disclosure relate to the design of light emitting diodes (LEDs). As the physical size of LEDs is reduced, efficiency losses due to surface recombination become ever more significant as a factor impacting overall performance. In particular, non-radiative recombination of charge carriers at and/or near the sidewalls of an LED mesa is a major contributor to reduced internal quantum efficiency (IQE) and reduced external quantum efficiency (EQE). In non-radiative recombination, charge carriers recombine to release phonons (heat) instead of photons. Non-radiative recombination can occur as a result of surface defects, such as dangling bonds created along mesa sidewalls as a result of etching mesas from a layered epitaxial structure. Non-radiative recombination is a challenging problem for micro-LEDs because such LEDs tend to have a high surface to volume ratio, between the surface area of the mesa sidewalls and the volume of the micro-LED.

### SUMMARY

The present disclosure relates to LED devices and methods of fabricating LED devices. In certain aspects, forming an LED may involve shaping a semiconductor structure into a mesa. The semiconductor structure may include a stack of epitaxial layers comprising oppositely doped (e.g., p-type and n-type) semiconductor layers and light emitting layers. Embodiments described herein are applicable to mesas of different shapes including, for example, vertical mesas and parabolic mesas. Multiple mesas can be formed concurrently, through etching and other semiconductor processing techniques, to form one or more LED devices for use in an LED display. In general, the light emitting region of an LED is an active region that includes at least one quantum well (QW). Charge carriers (electrons and holes) may be confined and recombine in the QW(s) to release energy in the form of photons, i.e., light.

In certain aspects, a semiconductor structure usable for forming one or more LED devices is a three-dimensional (3D) structure that includes a matrix of cells, e.g., a two-dimensional (2D) array of cells. Each cell is a light emitting cell within a mesa corresponding to an individual pixel. A cell has an active region comprising one or more QW structures. A QW structure includes at least one quantum well and may, for example, comprise a layer of quantum well material sandwiched between layers of quantum barrier (QB) material. In general, a QB material is any semiconductor material having a wider bandgap compared to the quantum well material in the cells. In some embodiments, multiple cells (e.g., the entire matrix or a sub-matrix) may be combined into a single LED. Multiple cells can be combined to form a single LED through providing the cells with one or more shared contacts or electrodes (e.g., a shared p-contact and/or a shared n-contact). Alternatively, the matrix can be partitioned such that an individual cell corresponds to a standalone LED.

In certain aspects, the cells of the matrix are quantum mechanically isolated from each other by an undoped QB layer. In particular, the undoped QB layer may operate to reduce or prevent migration of charge carriers (e.g., lateral diffusion across a mesa sidewall), thereby substantially confining the carriers to within the cells. The undoped QB layer comprises a QB material and may be deposited around the sidewalls of the mesas. In some embodiments, the undoped QB layer is in direct contact with the sidewalls and covers not only the sidewalls, but also the top surfaces of the mesas. The undoped QB layer may at times be referred to herein as a “flattening layer”. However, as discussed below, a flattening layer can include more than just an undoped QB layer. For example, in some embodiments, the flattening layer may include multiple QB layers (some of which may be doped), one or more electron blocking layers (EBLs), and/or one or more doped semiconductor layers (e.g., a lightly doped p-type semiconductor layer).

In certain aspects, the undoped QB/flattening layer described above may operate as a sacrificial layer that protects the quantum well structure(s) within each cell during a mesa pixelation process in which a semiconductor structure is etched (e.g., using dry etching) to define the mesa shape of the pixels. For example, as discussed below, the semiconductor structure may be subjected to an initial etch process that cuts into an n-doped (n-type) semiconductor and an active region (e.g., one or more QWs) as part of creating the matrix of cells. Following the initial etch, the undoped QB layer may be deposited (e.g., epitaxially grown) over the semiconductor structure to at least partially fill spaces between the mesas. One or more additional layers of the semiconductor structure, e.g., a layer comprising a p-type semiconductor, may be formed over the undoped QB layer. The semiconductor structure can then be etched again to further define the mesas. This second etch step can be configured to cut into the undoped QB layer without touching the mesa sidewalls, and thus the QWs within the cells. For example, a remaining portion of the undoped QB layer can thinly cover the mesa sidewalls. The resulting semiconductor structure may have significantly fewer sidewall defects compared to conventional mesa pixelation techniques, thereby further reducing non-radiative recombination at the sidewalls.

The undoped QB layer described above provides several benefits. For example, the wider bandgap of the undoped QB layer provides for effective quantum confinement of carriers within the cells. Being undoped also contributes to current confinement and prevention of carrier leakage across the mesa sidewalls. The undoped QB layer can be formed with a thickness suitable for protecting the cells against etch damage during the mesa pixelation process. The undoped QB layer can be sized to take up a relatively large proportion of the width of each pixel, which can effectively improve light extraction efficiency through reducing the size of the light-emitting active area in the pixel. Accordingly, the techniques described herein can be applied to form highly efficient LEDs (e.g., an LED array comprising micron or nanometer scale pixels) that have little etch damage.

### BRIEF DESCRIPTION OF THE DRAWINGS

Aspects of the disclosure are illustrated by way of example.

FIG. 1 illustrates an example of an LED, according to some embodiments.

FIG. 2 illustrates an example of a semiconductor structure from which one or more LEDs can be formed.

FIG. 3 illustrates an example of a semiconductor structure including a segmented active region, according to some embodiments.

FIG. 4 shows cross-sectional views of some example implementations of the semiconductor structure in FIG. 3.

FIG. 5A illustrates the effect of isolated quantum well (QW) structures in a QW matrix, according to some embodiments.

FIG. 5B shows an example of sub-optimal isolation.

FIGS. 6A and 6B illustrate the effect of thicker versus thinner quantum wells.

FIG. 7 illustrates an example of ridges formed on a substrate, according to some embodiments.

FIG. 8 illustrates examples of templates on which ridges or grooves can be formed, according to some embodiments.

FIG. 9 illustrates examples of multiple quantum wells (MQWs) grown on templates, according to some embodiments.

FIG. 10 illustrates an example of a process for creating a semiconductor structure from a template having existing quantum wells, according to some embodiments.

FIGS. 11A and 11B illustrate an example of a process for creating an LED device from a template, according to come embodiments.

FIG. 12 shows an example of dry-etch induced defects along the sidewalls of a mesa.

FIG. 13 is a flowchart illustrating a method for forming an LED device, according to some embodiments.

FIGS. 14A-14C illustrate an example of a process for forming an LED device, according to certain embodiments.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label with a second label (e.g., an alphabetical label) that distinguishes among the similar components. If only the first reference label is used in the specification, the description is applicable to any one of the similar components having the same first reference label irrespective of the second reference label.

### DETAILED DESCRIPTION

The present disclosure generally relates to LED devices and methods of fabricating LED devices. Aspects of the disclosure also relate to preventing or minimizing non-radiative recombination in LED devices. An LED can include an active (light-emitting) region having one or more quantum wells (QWs). In certain aspects, a semiconductor structure used to form one or more LEDs includes a matrix of cells. The matrix can be arranged as a two-dimensional (2D) array in which each cell comprises one or more QW structures. Each cell can be formed into a mesa through etching the semiconductor structure (e.g., using dry etching). As discussed below, the matrix can be formed in various ways. In one example, quantum wells may be epitaxially grown on a patterned template, e.g., a template corresponding to one or more layers of the semiconductor structure that have been etched to define a series of ridges or grooves. However, in some embodiments, the quantum wells may be grown as part of forming the template, which is then etched to create the matrix. The resulting structure can be subjected to further processing including, for example, etching performed as part of a mesa pixelation process.

Described herein are various techniques for quantum mechanically isolating active regions in an LED device using one or more quantum barrier (QB) layers. In some embodiments, the one or more QB layers include an undoped QB layer comprising a semiconductor material that has a wider bandgap compared to the quantum well material of the QWs. The undoped QB layer may operate to reduce or prevent migration of charge carriers (e.g., lateral diffusion across a mesa sidewall), thereby substantially confining the carriers to within the cells. When the carriers are confined in this manner, the level of non-radiative recombination activity at or near the sidewalls is limited, resulting in improved internal quantum efficiency (IQE) and improved external quantum efficiency (EQE).

In addition to providing quantum mechanical isolation, the undoped QB layer may, in some embodiments, operate as a protective layer against dry etch induced damage to the QWs. Dry etching is a mechanical process that tends to produce a large amount of surface defects. For example, when dry etching is used to form a mesa, the sidewall surfaces produced by the etch process may include one or more types of Shockley-Read-Hall (SRH) recombination defects, such as vacancies, impurities, interstitials, dangling bonds, and/or point defect complexes. All of these types of defects can lead to non-radiative recombination, and therefore loss of efficiency. The undoped QB layer can be formed with a thickness suitable for protecting the cells against etch damage during the mesa pixelation process, thereby reducing the occurrence of such defects.

In certain embodiments, one or more additional layers may be formed on top of the undoped QB layer. For example, the undoped QB layer can be located between the QWs and a doped (e.g., p-type) semiconductor layer. The undoped QB layer can be formed to include a substantially flat surface suitable for epitaxial growth of the doped semiconductor layer. Making the growing surface flat may in turn cause the doped semiconductor layer to be flat, which can facilitate other processing steps, e.g., to enable a p-type layer to be more uniformly coated with a reflective material that enhances light extraction efficiency. Alternatively, the undoped QB layer may initially have a non-flat surface onto which the doped semiconductor layer is grown, but the growth conditions for the doped semiconductor layer may be controlled such that both the doped semiconductor layer and the undoped QB layer ultimately become flat. Accordingly, the undoped QB layer is referred to herein as a “flattening layer”. Additionally, in some embodiments, the flattening layer can be multiple layers including, for example, multiple QB layers (some of which may be doped), one or more electron blocking layers (EBLs), and/or one or more doped semiconductor layers (e.g., a lightly doped p-type semiconductor layer).

As used herein, the term “micro-LED” refers to an LED having a linear dimension less than about 200 microns or micrometers (μm). For example, a micro-LED may have a diameter of less than 200 μm, less than 100 μm, less than 10 μm, or even smaller in some instances.

As used herein, a “multiple quantum well cell” or “MQW cell” refers to a cell having more than one quantum well. An MQW cell may include multiple layers of quantum well material, with the quantum well layers being separated by QB layers and possibly other types of layers. Further, unless explicitly stated otherwise or indicated by context, a “QW cell” may refer to an MQW cell or a cell having a single quantum well. As indicated above, a cell can include one or more QW structures. Accordingly, an MQW cell may correspond to a single QW structure having multiple quantum wells, multiple QW structures that each have a single quantum well, or multiple QW structures that each have multiple quantum wells. Other configurations of QW cells may also be possible in view of the present disclosure.

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

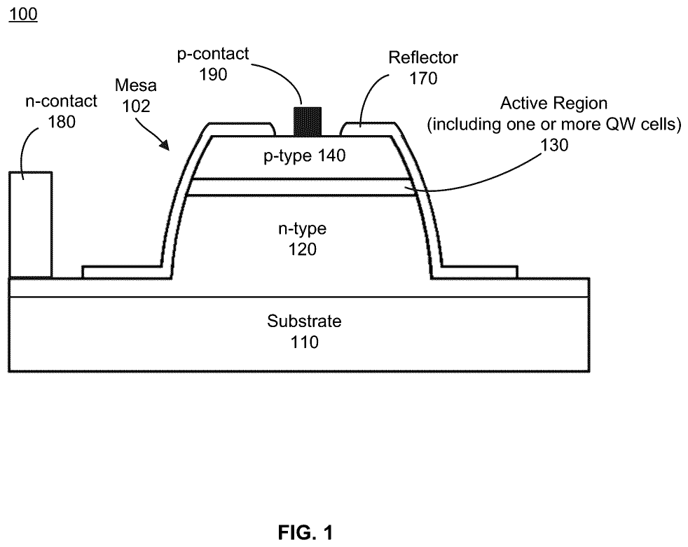

FIG. 1 illustrates an example of an LED 100, according to some embodiments. The LED 100 includes a mesa 102 formed from a semiconductor structure. The semiconductor structure can include multiple layers of semiconductor materials, such as a semiconductor layer 120, a semiconductor layer 140, and one or more layers that form an active region 130. The active region 130 may be configured to emit incoherent light and, as shown in FIG. 1, can include a matrix of cells containing QW structures (also referred to herein as a quantum well matrix or “QW matrix”). Further, LED 100 may be a micro-LED having a lateral dimension, or diameter, of less than 100 micrometers (e.g., under 10 micrometers). The semiconductor structure of the LED 100 may be made of inorganic materials. For example, the semiconductor structure may include multiple layers of III-V semiconductor materials. A III-V semiconductor material may include one or more Group III elements, such as aluminum (Al), gallium (Ga), or indium (In), in combination with a Group V element, such as nitrogen (N), phosphorus (P), arsenic (As), or antimony (Sb).

The semiconductor structure of the LED 100 may be manufactured by growing multiple epitaxial layers on a substrate, in one or more chambers, using techniques such as molecular beam epitaxy (MBE), metalorganic vapor-phase epitaxy (MOVPE), also known as organometallic vapor-phase epitaxy (OMVPE) or metalorganic chemical vapor deposition (MOCVD), or physical vapor deposition (PVD), such as pulsed laser deposition (PLD). For example, the semiconductor layers may be grown layer-by-layer on a substrate with a certain crystal lattice orientation, such as a sapphire, quartz, gallium nitride (GaN), gallium arsenide (GaAs), gallium phosphide (GaP). The silicon substrate may be cut in a specific direction to expose a specific plane as the growth surface.

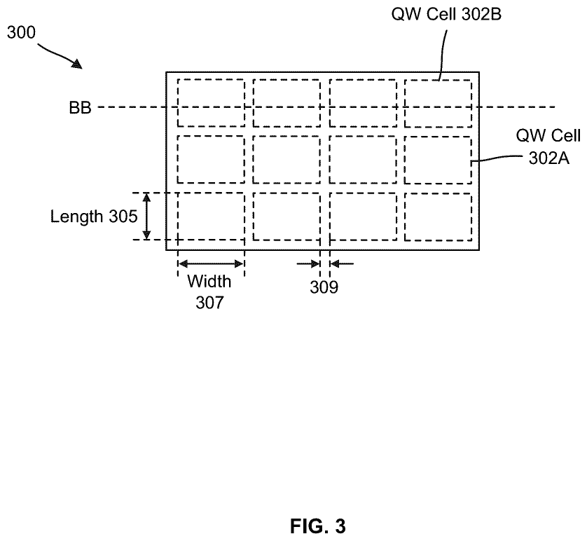

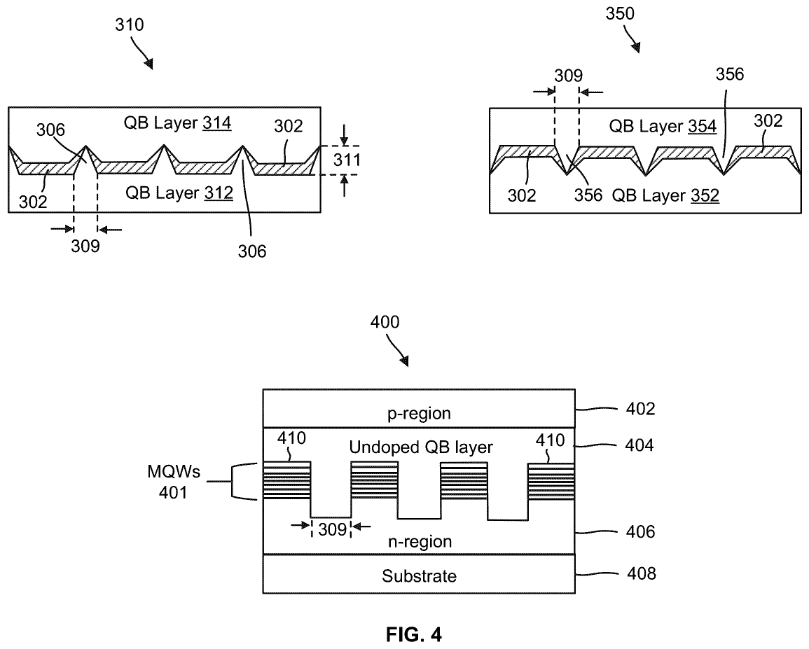

LED 100 may include a substrate layer 110, which may include, for example, an aluminum oxide (Al₂O₃) substrate (“sapphire” substrate) or a GaN substrate. The semiconductor layer 120 may be epitaxially grown on substrate layer 110. Semiconductor layer 120 may include a Group III-V material, such as GaN, and may be p-doped (e.g., with Mg, Ca, Zn, or Be) or n-doped (e.g., with Si or Ge). In the example shown in FIG. 1, layer 120 is an n-type doped semiconductor material. The active region 130 may include one or more layers grown on semiconductor layer 120. For example, the active region 130 may include one or more indium gallium nitride (InGaN) layers, one or more aluminum indium gallium phosphide (AlInGaP) layers, or one or more GaN layers, which may form one or more heterostructures, such as one or more quantum wells. In the example of FIG. 1, the active region 130 can include one or more QW cells. For the sake of simplicity, the QW cells are not shown in FIG. 1. Examples of matrices and QW cells formed from matrices are described below, for instance, in connection with FIGS. 3 and 4.

The quantum wells within the active region 130 may be formed by a set of QW layers, with each QW layer corresponding to a separate quantum well and adjacent pairs of QW layers being separated by one or more intervening quantum barrier (QB) layers. A QB may comprise any semiconductor material having a wider bandgap relative to the QW that the QB quantum mechanically confines or isolates. Accordingly, the active region 130 may include a wider bandgap semiconductor layer situated between a pair of narrower bandgap QW layers or, more generally, a layered structure that alternates between QB layers and QW layers. However, in some embodiments, an LED may include only one quantum well layer in the active region.

The semiconductor layer 140 may be epitaxially grown on the active region 130. Semiconductor layer 140 may include a III-V material, such as GaN, and may be p-doped (e.g., with Mg, Ca, Zn, or Be) or n-doped (e.g., with Si or Ge). In the example shown in FIG. 1, layer 140 is a p-type doped semiconductor material. Semiconductor layer 120 and semiconductor layer 140 sandwich the active region 130 to form the light emitting diode. For example, LED 100 may include a layer of InGaN situated between a layer of p-type GaN doped with magnesium and a layer of n-type GaN doped with silicon or oxygen. In some embodiments, LED 100 may include a layer of AlInGaP situated between a layer of p-type AlInGaP doped with zinc or magnesium and a layer of n-type AlInGaP doped with selenium, silicon, or tellurium.

To make electrical contact with the semiconductor layer 120 (e.g., an n-GaN layer) of the diode and to more efficiently extract light emitted by the active region 130, the semiconductor layers may be etched to expose semiconductor layer 120 and form a mesa structure (the mesa 102) that includes the layers 120 and 130 as well as the layers of the active region 130. The mesa structure may confine carriers within the injection area of the device. Etching the mesa structure may lead to the formation of mesa sidewalls—also referred to herein as facets—that may be non-parallel with, or in some cases, orthogonal, to the growth planes. A reflective layer 170 may be formed on the sidewalls of the mesa structure. Reflective layer 170 may include an oxide layer, such as a silicon oxide (SiO₂) layer, and may act as a reflector to reflect emitted light out of LED 100. A contact 180, which may comprise a metal, such as Al, Au, Ni, Ti, or any combination thereof, or a non-metal conductive material, shown as a n-contact in this figure, may be formed on semiconductor layer 120 and may act as an electrode of LED 100. In addition, another contact 190, such as an Al/Ni/Au metal layer, shown as a p-contact in this figure, may be formed to make ohmic contact with semiconductor layer 140 to act as another electrode of LED 100.

When a voltage signal is applied across the contacts 180 and 190, electrons and holes may be injected into and recombine in the active region 130, and the recombination of electrons and holes may result in emission of photons, i.e., light. The wavelength and energy of the emitted photons may depend on the energy bandgap between the valence band and the conduction band in active region 130. For example, InGaN active layers may emit green or blue light, while AlInGaP active layers may emit red, orange, yellow, or green light. The emitted photons may be reflected by the reflective layer 170 and may exit the LED 100, for example, from the bottom side (e.g., through the substrate 110). In some implementations, one or more optical elements (e.g., lenses or waveguides) may be disposed on the light exit surface of the LED 100 to further control the light emission of the LED 100, e.g., through collimation of the emitted light.

When the active region 130 includes more than one QW cell, the active region 130 may be divided into an array of smaller sub-regions (e.g., a 2D array of nano-sized cells), with each sub-region corresponding to a QW structure (e.g., an individual cell of a QW matrix) that is configured to emit light in response to the voltage applied across the contacts 180 and 190. Thus, the QW structures that form the LED 100 can be formed from the same QW matrix and may share the contact 180 and the contact 190 so as to be controlled simultaneously using the same voltage signal.

In the example of FIG. 1, the LED 100 has a parabolic mesa. Although the mesa 102 is shown as being parabolic, in some embodiments, the LED 100 may include a mesa of another shape, such as a planar, vertical, conical, or semi-parabolic, and where a base area of the mesa may be circular, rectangular, hexagonal, or triangular. For example, the LED 100 may include a mesa with a curved shape (e.g., paraboloid shape) or a non-curved shape (e.g., conic shape). The mesa may be truncated or non-truncated.

Additionally, although FIG. 1 shows only a single LED, it will be understood that an LED device may include multiple LEDs, e.g., a one-dimensional or two-dimensional array of LEDs, where each LED in the array corresponds to an instance of the LED 100. In some implementations, two or more LEDs in the same array may share a contact (e.g., a shared n-contact and/or a shared p-contact). The LEDs in an LED array may be formed from a shared semiconductor structure, e.g., a stack of semiconductor layers on a substrate. The LEDs may be formed through etching the shared semiconductor structure into a plurality of mesas with voids or trenches between adjacent mesas. In the example of a micro-LED with a lateral dimension of less than 10 micrometers, the void or trench between mesas may be in the range of 0.05 to 7 micrometers in width, with a variety of pitch distances (e.g., center-to-center distance between adjacent mesas) being possible. The number of mesas along a first dimension may be in the thousands, and the number of mesas along a second dimension may also be in the thousands. Just as an example, an array may comprise 1,500 mesas by 1,000 mesas. In another example, an array may comprise 2,000 mesas by 1,500 mesas.

Surface imperfections on the facets of each mesa may contribute to undesirable surface recombination that decreases the efficiency of each LED. At the mesa facets, the atomic lattice structure of the n-type doped semiconductor material, light emitting material, and p-type doped semiconductor material ends abruptly. At these surfaces, atoms of the semiconductor material lack neighbors to which bonds may be attached. This results in “dangling bonds,” which are characterized by unpaired valence electrons. These dangling bonds create energy levels within the bandgap of the semiconductor material that otherwise would not exist, causing non-radiative electron-hole recombination at or near the surface of the semiconductor material. Other types of surface defects can also contribute to non-radiative recombination including, for example, vacancies, impurities, interstitials, and point defect complexes. Such defects may also be present at or near the facets of the mesas (e.g., extending to a certain depth along the sidewall surfaces). The number of defects depends on how the LEDs are formed, for example, what growth and etch processes are used to form the mesas. Techniques for minimizing the number of defects that lead to non-radiative recombination are discussed below.

The effects of non-radiative recombination are especially pronounced as the physical size of an LED mesa is reduced to diameters of 10 micrometers and below, especially 5 microns and below. In larger LEDs, e.g., LEDs with a diameter greater than 50 micrometers, the LED area affected by non-radiative surface recombination is relatively small. For example, assuming a diffusion length of 1 micrometer, the effects of non-radiative surface recombination may be limited to those areas within approximately 1 micrometer of the mesa facets. For an LED having a diameter of 50 micrometers, only a small fraction of the interior of the LED is within 1 micrometer of the LED's surface—i.e., mesa facet. Therefore, even though much of the surface recombination activity in an LED occurs within the quantum well layer(s), the LED areas affected by non-radiative surface recombination would not include a significant portion of the active region. By contrast, in a much smaller LED, e.g., 2 micrometers in diameter, the area affected by surface recombination may be quite significant. In such a case, a large percentage of recombination activity may correspond to non-radiative surface recombination near the mesa facets. Thus, micro-LEDs are particularly susceptible to reduced efficiency in comparison to traditional LEDs, e.g., LEDs with diameters of several millimeters.

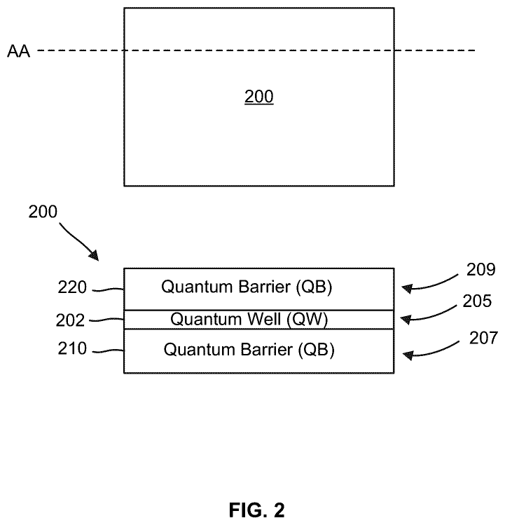

FIG. 2 shows a top-down view of a semiconductor structure 200 from which one or more LEDs can be formed. FIG. 2 includes a cross-section of the semiconductor structure 200 along line AA. As seen in the cross-sectional view, the semiconductor structure includes a QW layer 202 situated between a first QB layer 210 and a second QB layer 220. The QW layer 202 corresponds to a quantum well from which light can be emitted after the semiconductor structure 200 has been processed into one or more LEDs. The QW layer 202 can include, for example, one or more of the following: indium gallium nitride (InGaN), indium gallium phosphide (AlInGaP), indium gallium phosphide (InGaP), gallium arsenide phosphide (GaAsP), or gallium nitride (GaN). The layers 202, 210, and 220, in particular the QW layer 202, may correspond to an active region of an LED. Additional layers that may be included in an LED are omitted from FIG. 2 for the sake of simplicity. For example, from the discussion of FIG. 1, it will be understood that a p-doped semiconductor layer may be formed on top of the QB layer 220 (e.g., directly on the QB layer 220), and an n-doped semiconductor layer may be formed below the QB layer 210. Further, the various layers of the LED, including the layers 202, 210, and 220, may each be grown on top of a substrate, e.g., the substrate 110.

Although depicted as a single layer, the QW layer 202 can be an MQW layer containing a plurality of QW layers that are separated by “local” quantum barriers. In other words, separate from the QB layers 210 and 220, the area corresponding to the QW layer 202 could include one or more additional QB layers. As mentioned above, a QB may comprise any semiconductor material having a wider bandgap relative to the QW that the QB quantum mechanically confines or isolates. In the context of the semiconductor structure 200, this means that the QB layers 210 and 220 have a wider bandgap than the quantum well in the QW layer 202. Similarly, if the QW layer 202 is an MQWs layer, the local quantum barriers within the QW layer 202 would have a wider bandgap than the quantum wells in the QW layer 202.

The semiconductor material from which the local QBs (if any) in the QW layer 202 are formed can be the same or different than that from which the QB layers 210 and 220 are formed. Likewise, the QB layer 210 can be formed from the same or a different semiconductor material than the QB layer 220. In some embodiments, the materials from which the local QBs, the QB layer 210, and the QB layer 220 are formed may be identical or at least partially overlapping. A quantum barrier layer may, for example, include gallium nitride (GaN), aluminum gallium nitride (AlGaN), indium gallium nitride (InGaN), or aluminum gallium indium nitride (AlGaInN). Other suitable materials for a quantum barrier layer include, for example, aluminum indium phosphide (AlInP), aluminum gallium arsenide (AlGaAs) or aluminum indium gallium arsenide phosphide (AlInGaAsP). Additionally, a quantum barrier layer may be configured as a hybrid barrier with sub-layers that are formed from different materials. For example, the QB layer 210 and/or the QB layer 220 could include a thinner AlGaN barrier followed by a thicker GaN barrier. An example composition of the semiconductor structure 200 is as follows: QB layer 210—AlGaInP, QW layer 210—GaInP, QB layer 220—AlGaInP.

The semiconductor structure 200 can be etched into one or more mesa shapes, each mesa corresponding to a separate LED. However, for discussion purposes, assume that the entire semiconductor structure 200 will be etched into a single mesa with sidewalls that extend along the edges of each of the layers 202, 210, and 220. Mesa etching tends to expose surface imperfections along the resulting facets (e.g., the mesa sidewalls), surface imperfections which lead to non-radiative recombination. Such surface imperfections are often more prevalent in the QW layers than the quantum barrier layers. For example, 90% of the surface imperfections along a sidewall of the mesa could lie along the edges of the QW layer 202 (e.g., an edge 205), while the remaining 10% may be distributed along edges of the QB layers 210 and 220 (e.g., edges 207 and 209, respectively). Moreover, the effects of the surface imperfections within the QW layer 202 may be more severe since QW layers are more prone to surface recombination. To reduce non-radiative recombination, aspects of the present disclosure relate to forming an active region that is segmented into discrete QW structures instead of having a monolithic active region such as the active region corresponding to the QW layer 202. An example of a segmented active region is shown in FIG. 3.

Additionally, as discussed above, some embodiments may feature an undoped QB layer that provides quantum mechanical isolation as well as etch protection. In the example of FIG. 2, the undoped QB layer may correspond to the QB layer 210 and/or the QB layer 220. Alternatively, the undoped QB layer may be an additional layer onto top of the QB layer 220 and/or below the QB layer 210. Examples of semiconductor structures featuring an undoped QB layer are described below.

FIG. 3 shows a top-down view of a semiconductor structure 300 including a segmented active region, according to some embodiments. FIG. 4 (discussed below) includes cross-sectional views, taken along line BB, of some example implementations of the semiconductor structure 300. As with FIG. 2, additional layers (e.g., layers analogous to substrate 110, n-type layer 120, and p-type layer 140 in FIG. 1) are omitted. As seen in the top-down view, the active region is divided into a plurality of cells 302, e.g., a first cell 302A and a second cell 302B. Each cell 302 is a QW structure that has a substantially rectangular (e.g., square) profile, defined by a length 305 and a width 307. However, other cell shapes are possible, for example, hexagonal. In the example of FIG. 3, the cells 302 form a two-dimensional array in which the cells 302 are arranged into rows and columns, with adjacent cells being spaced apart by a stripe width or distance 309. The distance 309 may be substantially uniform throughout the active region such that the distance to an adjacent cell is approximately the same along each side of a cell. However, as indicated in the cross-sectional views in FIG. 4, the distance between cells may vary along the vertical direction such that adjacent cells 302 approach or meet to define the boundaries for a ridge-shaped portion of a QB layer. If the semiconductor structure 300 is used to form a micro-LED, then the cells 302 may be nanoscale. For example, the distance 309 may range from 25 to 100 nanometers (nm), the length 305 and the width 307 may range from 50 to 200 nm, and the height (311) of the QW cells may range from 60 to 90 nm.

In the example of FIG. 3, each cell 302 may correspond to a single QW structure having one or more QW layers. Further, each cell 302 may be etched into a mesa shape to separate the cells into regions corresponding to individual pixels (e.g., where each cell corresponds to a single LED) or into sub-pixels (e.g., where multiple cells are combined into a single LED). However, in some embodiments, a cell may include multiple (two or more) QW structures. For example, a QW cell may correspond to the cell 302A in combination with the cell 302B, in which case the semiconductor structure 300 may be etched to define a single mesa around both the cell 302A and the cell 302B.

FIG. 4 shows cross-sectional views of example semiconductor structures that can be formed from a matrix as described above. FIG. 4 includes a first semiconductor structure 310, a second semiconductor structure 350, and a third semiconductor structure 400. The semiconductor structures each include QW structures corresponding to cells 302 of the matrix shown in FIG. 3. The surrounding layers are omitted from the depictions of the semiconductor structures 310 and 350 but are shown in the semiconductor structure 400 for added clarity.

Semiconductor structure 310 includes a QB layer 312 and a QB layer 314. In this example, each cell 302 corresponds to an individual light emission region and includes at least one quantum well. In some embodiments, a cell 302 is an MQW cell that includes two or more QW layers and at least one local QB layer. The cells 302 are sandwiched between the QB layers 312 and 314. The QB layer 312 and the QB layer 314 may correspond to the first QB layer and the last QB layer in the semiconductor structure 310, respectively. That is, the QB layer 312 can be the first quantum barrier grown, and the QB layer 314 can be the last quantum barrier grown. The QB layer 312 includes structures 306 that project into the area between adjacent cells 302 to separate the cells. Each structure 306 is bounded by the sidewalls of a pair of adjacent cells 302. The structures 306 are ridge-shaped and taper so that the distance between adjacent cells decreases in the direction of the QB layer 314. As indicated above, the cells 302 can be nanoscale. Accordingly, the structures 306 can also be nanostructures. The QB layer 312, in particular the structures 306, operates to quantum mechanically isolate the cells 302. The mechanism by which such isolation occurs is described below.

Semiconductor structure 350 includes a QB layer 352 and a QB layer 354. In the semiconductor structure 350, the cells 302 are quantum mechanically isolated by structures 356 located in the QB layer 354. Like the structures 306, the structures 356 can be nanostructures bounded by the sidewalls of adjacent cells 302. The structures 356 taper toward the QB layer 352 and are shaped similarly to the structures 306, but oriented in the opposite direction.

Semiconductor structure 400 includes a p-region 402 (e.g., the semiconductor layer 140 in FIG. 1), an undoped QB layer 404, an n-region 406 (e.g., semiconductor layer 120), and a substrate 408 (e.g., substrate 110). The undoped QB layer 404 can be a flattening layer that is formed on top of cells 410. In the example shown, each cell 410 of the semiconductor structure 400 is an MQW cell with MQWs 401. The MQWs 401 are heterostructures comprising multiple layers of QW material separated by local quantum barriers. In some embodiments, the cells 410 of the semiconductor structure 400 may comprise multiple QW structures. For example, a cell 410 may correspond to a combination of cell 302A and cell 302B in FIG. 3. For illustration purposes, the cells 410 are shown as being spaced apart by a gap corresponding to the distance 309 discussed above and, as such, represent individual cells 302.

As shown in FIG. 4, each cell 410 of the semiconductor structure 400 has a mesa shape, with the sidewalls of the mesa extending into the n-region 406. However, in other embodiments, the mesas may not extend beyond the MQWs 401. In the example shown, the cells 410 have vertical sidewalls such that the mesas are shaped like 3D rectangles, but the shape of the mesas can vary depending on implementation. For example, the cells 410 may have angled or non-vertical sidewalls such the mesas have a trapezoidal (e.g., a truncated pyramid) or other geometric shape.

Undoped QB layer 404 may comprise a layer of undoped semiconductor material formed directly over the cells 410. Although shown as a single layer, the region labeled as being the undoped QB layer 404 may include additional layers. For example, in some embodiments, the region associated with reference label 404 may include, in addition to an undoped QB layer, one or more additional QB layers (some of which may be doped), one or more EBLs (e.g., a p-type EBL), one or more doped semiconductor layers (e.g., a lightly doped p-type semiconductor), one or more capping layers (e.g., a 0.5 to 1 nm undoped capping layer comprising AlN or GaN), one or more strain compensation layers (e.g., an AlGaN strain compensation layer), and/or other types of semiconductor layers. The undoped semiconductor material has a wider bandgap compared to the quantum well material in the MQWs 401 and may comprise chemical elements that are also found in the MQWs 401. For example, the MQWs 401 may correspond to an active region having layers of InGaN or some other nitride (e.g., in the case of a green or blue LED). As such, the undoped semiconductor material may include nitride (e.g., GaN) when the active region is nitride-based. Similarly, the undoped semiconductor material may include phosphide (e.g., GaP) when the active region is phosphide-based (e.g., AlInGaP, as in the case of a red or yellow LED). Further, the bandgap of the undoped semiconductor material may be the same or different from the bandgap of the doped semiconductor regions. For example, an undoped QB layer comprising GaN can be used in combination with a p-region comprising p-doped GaN, in which case the bandgaps of the undoped QB layer and the p-region may be the same.

The semiconductor structures shown in FIG. 4 can be formed in various ways. For example, semiconductor structures 310 and 350 may be formed using a template structure that has been etched to define ridges or grooves. As explained below, the QWs in the semiconductor structure can be grown after the template has been etched or etched as part of the template itself. In some examples, the template is not etched to define ridges or grooves. For instance, the semiconductor structure 400 can be formed using a two-step etching process, discussed below. The semiconductor structure 400 can be formed more readily compared to the semiconductor structures 310 and 350 since the sidewalls of the cells 410 do not have to conform exactly to the shape of a ridge or groove. Although it is possible to define a ridge or groove shape, e.g., using dry etching, formation of ridges and grooves typically involves more precise control over the etch conditions.

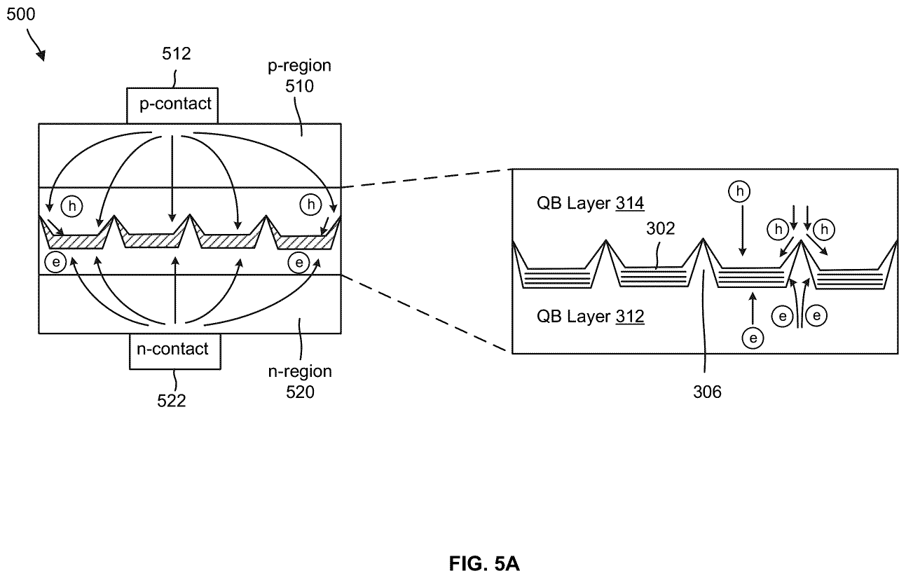

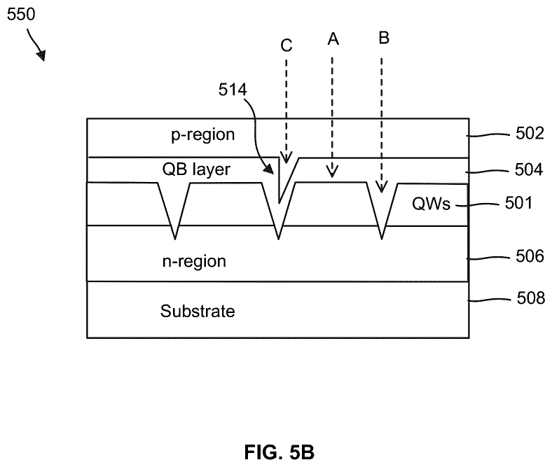

FIG. 5A illustrates the effect of isolated QW structures in a QW matrix, according to some embodiments. The example of FIG. 5A is based on a ridge-type structure similar to the semiconductor structure 310 in FIG. 4. Carriers can be similarly isolated with the aid of a QB layer in other structures that include a QW matrix, such as the semiconductor structure 350 or the semiconductor structure 400. In FIG. 5A, an LED 500 is configured to include an active region corresponding to the semiconductor structure 310. The active region of the LED 500 is shown in enlarged detail in the inset image, where the cells 302 are depicted as being MQW cells. The LED 500 further includes a p-region 510 (e.g., a region encompassing semiconductor layer 140 in FIG. 1), an n-region 520 (e.g., a region encompassing semiconductor layer 120), a p-contact 512, and an n-contact 522. When a voltage is applied across the p-contact 512 and the n-contact 522, charge carriers are mobilized toward the active region. Specifically, holes (h) are injected from the p-region 510 toward the quantum wells of the active region (the cells 302). Similarly, electrons (e) are injected from the n-region 520 toward the cells 302. When the electrons and holes recombine in the quantum wells, light is emitted.

As shown in FIG. 5A, the injected carriers exhibit a quantum mechanical preference for the flat (central) regions of the cells 302. In this example, the flat regions correspond to the bottom of each cell 302. Thus, the electrons and holes tend to move toward (and stay within) the bottoms of the cells 302, thereby maximizing their availability for radiative (light-emitting) recombination. In the example of semiconductor structure 350, the flat regions correspond to the tops of the cells 302.

One factor that may contribute to the preference of the carriers for the flat regions of the cells 302 is the structures 306 of the QB layer 312. The structures 306 provide lateral separation between adjacent QW structures to reduce or prevent migration (e.g., lateral diffusion) of carriers in a QW structure across the barrier provided by the QB layer 312. Consequently, migration of carriers to the etched mesa sidewall regions (where the defect density and thus non-radiative recombination may be high) is also reduced or prevented.

Another factor that may contribute to the preference of the carriers for the flat regions of the cells 302 is the non-uniform distribution of quantum well material within each cell 302. The QWs may be significantly thinner at the sloped (peripheral) regions of the cells 302, which are adjacent to and abut the structures 306. Further, the sloped regions of the cells may have a wider bandgap due to having a different proportion of quantum well material (e.g., lower indium content) relative to the central regions. The thinness and wider bandgap at the periphery of the cells 302 may further enhance the local confinement of carriers.

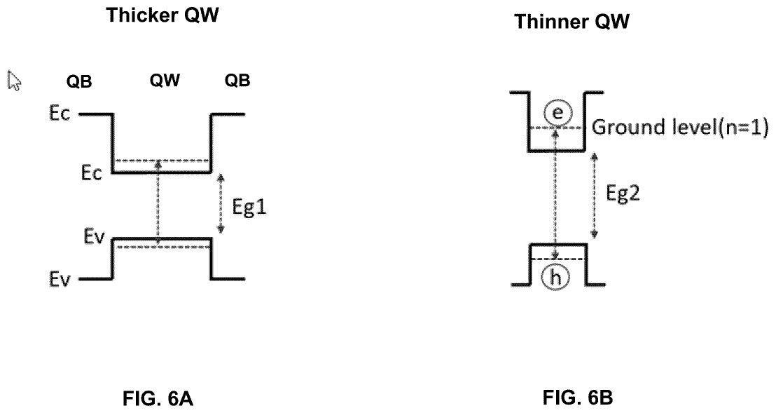

Having a wider bandgap at the cell periphery means injected charge carriers may diffuse to and be confined in the central region of the cell. Further, as the physical thickness of a QW decreases, the difference between the energy states of the charge carriers will increase correspondingly. For example, the difference between the ground level energy states of holes and electrons may become larger because the ground level energy state in a narrower QW may be increased in the case of an electron but decreased in the case of a hole. In other words, the average energy of electrons in a narrower QW will be higher than that of a wider QW. This is shown in FIGS. 6A and 6B and is another reason why charge carriers in the thinner QW areas may diffuse to and be confined in the central region, where the ground level energy state of electrons and the difference between ground level energy states of electrons and holes are lower.

FIG. 5B shows an example of sub-optimal isolation. In FIG. 5B, semiconductor structure 550 has a groove-type structure similar to the semiconductor structure 350. FIG. 5B is provided to illustrate the importance of having a flat QB layer of sufficient thickness to reduce or minimize carrier loss. The semiconductor structure 550 includes a p-region 502, a QB layer 504, an active region comprising a set of QW cells 501 (e.g., a 2D matrix of cells 501), an n-region 506, and a substrate 508. In this example, the QB layer 504 is generally flat but has a pitted region 514. Consequently, the p-region extends into the pitted region 514. When carriers (e.g., holes) are injected through channel A, the carriers have a tendency to flow into the QWs 501 due to the wider bandgap of the QB layer 504. For example, injected holes may encounter a uniformly distributed layer of quantum barrier material and, as a result, may prefer to flow into the QWs 501. When carriers are injected through channel B, the QB layer 504 is thick enough to cover the sidewalls of the QW cells, so the carriers also tend to flow into the QWs 501. However, when carriers are injected through channel C, the carriers can more easily flow through the sidewalls to participate in non-radiative recombination (e.g., with electrons from the n-region). Channel B is associated with the lowest probability of non-radiative recombination, followed by channel A, and channel C has the highest probability of non-radiative recombination.

Based on the example of FIG. 5B, it will be apparent that a groove-type or ridge-type structure is advantageous because such a structure provides for channels similar to channel A and channel B discussed above. A semiconductor structure without ridges or grooves (e.g., semiconductor structure 400) can also provide channels similar to channel A and channel B while avoiding scenarios corresponding to the injection through channel C. Carrier loss can be minimized provided that the QB layer 504 is substantially flat and thick enough to cover the sidewalls of the QW cells. For example, QB layer 504 may correspond to undoped QB layer 404. Therefore, while not strictly required, an undoped flattening layer can be provided as an effective isolation barrier.

To make the QB layer 504 flat, the surface morphology of the semiconductor structure can be controlled as the QB layer 504 and/or the p-region 502 is formed. For instance, flattening can be accelerated by increasing growth temperature, decreasing growth rate, adding a surfactant, and/or using other techniques that enhance the rate of lateral growth relative to vertical growth. Accordingly, in some implementations, an undoped QB layer (e.g., QB layer 404) may be grown to be less flat, but due to the growth conditions of one or more subsequent layers (e.g., the p-region 402), the undoped QB layer and the subsequent layer(s) may end up substantially flat or flatter. This has added benefits in terms of facilitating other process steps, such as forming a reflective layer (e.g., Al, Ag, Au, or some other metal) on top of the p-region.

FIGS. 6A and 6B illustrate the effect of thicker versus thinner quantum wells. FIGS. 6A and 6B each show a bandgap diagram for a heterostructure comprising a first QB followed by a QW and then a second QB which, in the case of semiconductor structure 310, may correspond to the QB layer 312, a QW cell 302, and the QB layer 314, respectively. In FIG. 6A, the quantum well is thicker compared to FIG. 6B. Thus, FIG. 6A may be more representative of the energy states in the central regions of the cells 302, whereas FIG. 6B may be more representative of the energy states at the edges of the cells 302. As shown in FIG. 6A, the difference between ground level energy states of the charge carriers is smaller in magnitude compared to the ground level energy state difference in FIG. 6B. Similarly, the bandgap (Eg1) between the conduction band (Ec) and the valence band (Ev) in FIG. 6A is smaller than the bandgap (Eg2) in FIG. 6B.

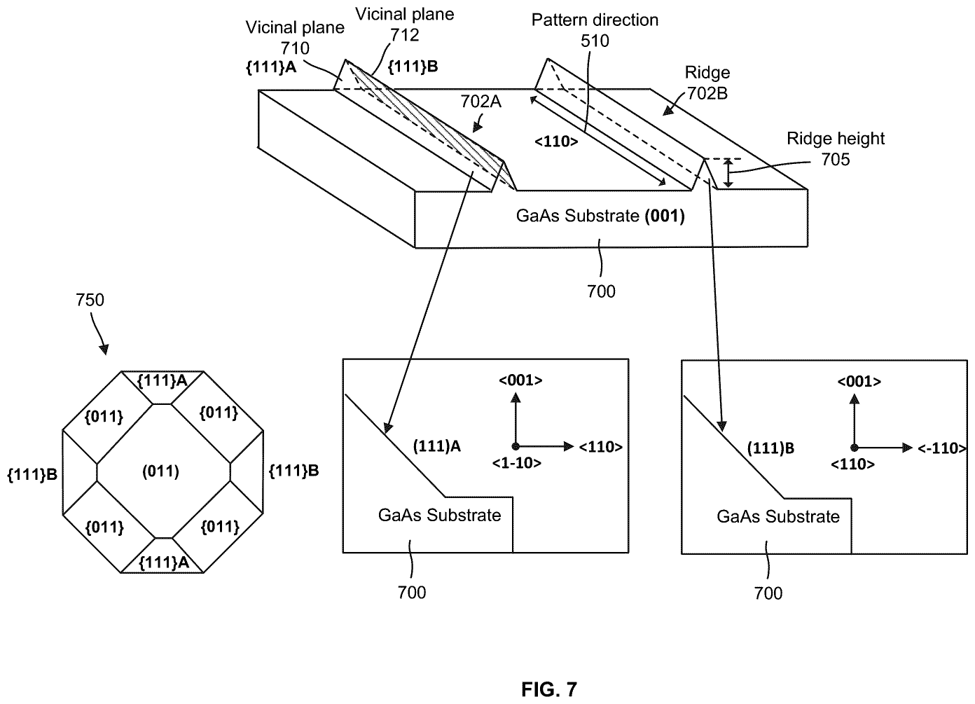

FIG. 7 illustrates an example of ridges 702A and 702B formed on a substrate 700. The ridges 702A, 702B define the borders of an area in which a QW cell can be grown. For simplicity, only two ridges are shown. However, it will be understood, for example, in view of the disclosure concerning FIG. 3, that additional ridges can be formed on the substrate 700 to fully enclose the perimeter of each area corresponding to a QW cell. Likewise, grooves can be formed to fully enclose the perimeter of each QW cell in a QW matrix.

Each ridge 702 is defined by a pair of surfaces corresponding to vicinal planes in the crystal lattice of the substrate 700. For example, the ridge 702A includes a vicinal plane 710 and a vicinal plane 712. The vicinal plane 712 is shown using cross-hatching. Both of the vicinal planes 710, 712 may be {111} planes. Here, curly brackets { } denote equivalent planes, angled brackets < > denote equivalent directions, and parentheses ( ) denote a specific plane, in accordance with Miller indices conventions. In FIG. 7, the substrate 700 comprises GaAs, which has a crystal structure 750. One side of each ridge corresponds to a {111}A plane, shown in the left inset image. The other side of the ridge corresponds to a {111}B plane, shown in the right inset image. Each ridge 702 has a height 705 that roughly corresponds to the height of QW cell. The ridges 702 can be formed through electron-beam (e-beam) lithography at an angle ranging from 50-60° to approximate the {111} planes, where the (001) plane corresponds to 0°, the (110) plane corresponds to 90°, and the {111} planes correspond to 54.7°. As shown in FIG. 7, the substrate 700 can be patterned along the <110> and <1-10> crystallographic directions to achieve a desired length for each ridge 702. Grooves may be formed in a similar manner, through appropriate selection of the angles and directions for patterning a template (e.g., the substrate 700).

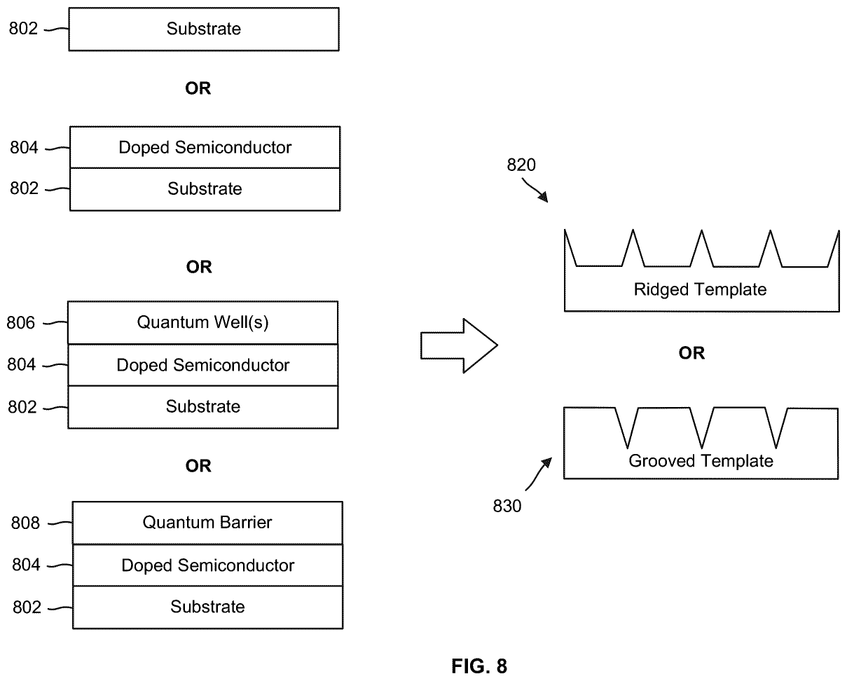

FIG. 8 illustrates examples of templates on which ridges or grooves can be formed. As shown in FIG. 8, a ridged template 820 or a grooved template 830 can be formed from a base template comprising a bare substrate 802 (e.g., a GaAs substrate). The base template can also include the substrate 802 in combination with one or more semiconductor layers grown on top. For example, the base template can include a doped semiconductor 804 (e.g., n-type or p-type). In some instances, the base template may even include one or more quantum wells 806. For example, substrate 802 may include GaAs, doped semiconductor 804 may include n-doped AlGaInP, and the quantum wells 806 may include MQWs epitaxially grown over the doped semiconductor 804 using metal organic chemical vapor deposition (MOCVD). Accordingly, grooves or ridges can extend to a depth that reaches the substrate 802, the doped semiconductor 804, and/or the quantum wells 806.

As yet another possibility, the base template may include the substrate 802, the doped semiconductor 804, and a quantum barrier 808. The quantum barrier 808 may, for example, correspond to the QB layer 312 or the QB layer 352 in FIG. 4. Based on the examples in FIG. 8, it will be understood that the ridged template 820 or the grooved template 830 can be etched into a three-dimensional (3D) shape having flat portions and sloped portions, with the sloped portions corresponding to areas between QW cells, e.g., the locations of nanostructures in a QB layer that will quantum mechanically isolate the QW cells. Further, the nanostructures of the QB layer may be etched into the QB layer (e.g., when the template includes the quantum barrier 808) or subsequently formed when a layer of quantum barrier material is grown over the template 820, 830 (e.g., as a final quantum barrier on top of the QW cells or as an initial quantum barrier between the doped semiconductor 804 and the QW cells).

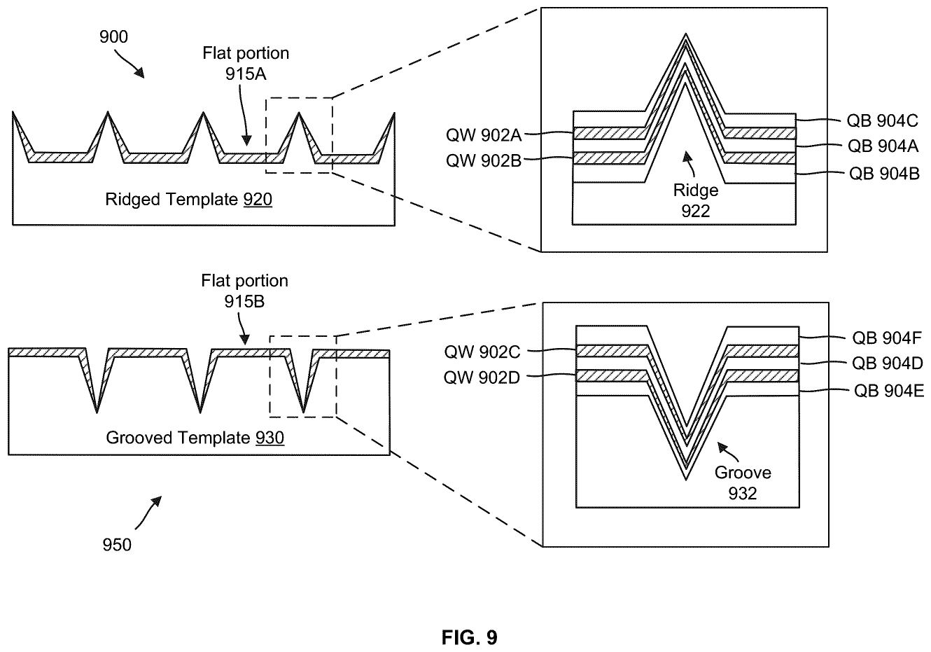

FIG. 9 illustrates examples of MQWs grown on templates. As shown, a semiconductor structure 900 may include a ridged template 920 with a QW 902A and a QW 902B between a QB 904A. The QW 902B may be formed over a QB 904B, with the QB 904B being the first quantum barrier layer grown on top of a ridge 922. An additional QB 904C may be grown on top of the QW 902A. Similarly, a semiconductor structure 950 may include a grooved template 930 with a QW 902C and a QW 902D between a QB 904D. The QW 902D may be formed over a QB 904E, with the QB 904E being the first quantum barrier layer grown on top of a groove 932. An additional QB 904F may be grown on top of the QW 902C.

The MQWs in FIG. 9 can be formed using epitaxial growth in which the ridge template 920 or the grooved template 930 is exposed to an appropriate composition of gases (e.g., a mix of Ga and In) to inject adatoms onto the exposed surfaces of the ridges or grooves. The vicinal surfaces along the ridges/grooves tend to have lower adatom density compared to the flat surfaces, e.g., a flat region 915A of a QW cell in the ridged template 920 or a flat region 915B of a QW cell in the grooved template 930. Consequently, the QWs 902 may be substantially thinner along the vicinal surfaces. As indicated in the discussion of FIGS. 6A and 6B above, thinner quantum wells are associated with higher energy states for electrons and higher differences between the ground level energy states of electrons and holes. Consequently, the thinner regions of the QWs 902 at the vicinal surfaces (e.g., along the {111} planes in FIG. 7) may contribute to quantum mechanical isolation of charge carriers injected into the flat regions of the quantum wells.

Additionally, as discussed above, the vicinal surfaces may have a wider bandgap compared to the flat regions due to a difference in composition. For example, the wider bandgap at the vicinal surfaces may be a result of fewer indium adatoms being deposited on the vicinal surfaces, and this may be another contributing factor to quantum mechanical isolation.

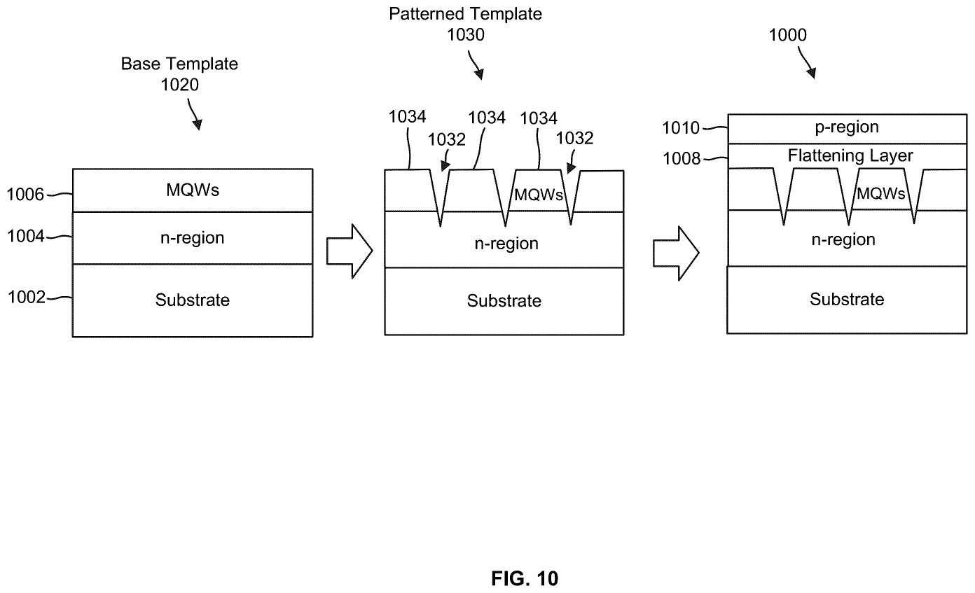

FIG. 10 illustrates an example of a process for creating a semiconductor structure 1000 from a template, according to come embodiments. FIG. 10 shows the semiconductor structure 1000 as having grooves. However, the techniques described in connection with FIG. 10 can be applied to form other types of semiconductor structures including, for example, the semiconductor structure 400 in FIG. 4. The process in FIG. 10 begins with a base template 1020, for example, a semiconductor structure including a substrate 1002, a doped-semiconductor layer (e.g., an n-region 1004), and an MQW layer 1006.

The n-region 1004 may include a layer of Group III-V material (e.g., AlGaInP) that has been doped with an n-type dopant, e.g., with selenium (Se) to form an n-AlGaInP layer. Alternatively, the Group III-V material of the n-region 1004 may be a nitride material (e.g., GaN). The MQWs layer 1006 corresponds to an active region for one or more LEDs and may include multiple layers of quantum well material separated by quantum barrier layers. For instance, the MQWs layer 1006 may include a stack of QB and QW layers, similar to FIG. 9. In particular, the MQWs layer 1006 may include alternating layers of QB and QW materials, with at least two QW layers operating as quantum wells. However, as discussed above, some embodiments may feature an active region having a single quantum well. The MQWs layer 1006 can be epitaxially grown prior to etching the base template 1020 into a patterned template 1030 having a matrix of QW cells (e.g., the cells 302 in FIG. 3). The quantum well material of the MQWs layer 1006 can be formed from a similar Group III-V material as the n-region 1004 but can be any narrow bandgap material compatible with the other layers in the semiconductor structure. For example, the quantum well material of the MQWs layer 1006 may include InGaN when the n-region includes GaN.

In the example of FIG. 10, the base template 1020 is etched (e.g., using e-beam lithography and dry-etching) to form grooves 1032 in the patterned template 1030. The grooves 1032 can be formed by etching along non-vertical directions, e.g., along vicinal planes similar to the ridge example in FIG. 7. Alternatively, when forming the semiconductor structure 400, the base template 1020 can be etched along a vertical direction to define substantially vertical sidewalls. As shown in the figure, the base template 1020 can be etched down to the n-region 1004. However, in some implementations, the etching may be terminated before reaching the n-region 1004. For example, the base template 1020 can be etched down to the final QB layer (not shown) before the n-region 1004.

The grooves 1032 may define the boundaries of QW cells 1034 that are arranged in a two-dimensional matrix, similar to the QW cells 302 in FIG. 3. For example, if a rectangular cross-sectional profile is desired for a QW cell 1034, the sides of each QW cell 1034 may correspond to the intersection of a first pair of grooves 1032 and a second pair of grooves 1032 that are orthogonal to the first pair of grooves. Together, both pairs of grooves may define the boundaries of a QW cell that has a three-dimensional shape similar to a truncated pyramid.

To form the semiconductor structure 1000, a flattening layer 1008 can be added on top of the MQWs layer 1006. The flattening layer 1008 may be epitaxially grown (e.g., to form an undoped QB layer comprising a nitride or phosphide) after surface preparation of the patterned template 1030. The surface preparation may involve a combination of ex-situ wet-etching and in-situ cleaning. For example, the patterned template 1030 can be chemically cleaned using ex-situ chemical wet-etch cleaning and in-situ thermo-chemical cleaning (e.g., annealing) to remove oxide and damage from the dry-etched surfaces, thereby reducing the number of surface defects. The thermo-chemical cleaning can be performed under high temperature in an epitaxial reactor, using one or more gases such as H₂ or NH₃.

In some embodiments, the ex-situ phase of the cleaning may involve different or additional agents, such as acetone, methanol, or deionized water in an ultrasonic bath, followed by an isopropyl alcohol rinse. Similarly, the in-situ phase of the cleaning may involve different or additional agents, such as AsH₃, PH₃ or N₂ prior to regrowth. The choice of cleaning agents may depend on how the template is structured, for example, on the material composition of the layer(s) that are etched during the patterning. After cleaning, the dry-etched surfaces may optionally be further repaired using multi-layer deposition to create a superlattice, e.g., by adding one or more additional layers of compatible semiconductor materials such as n-doped InGaN (n-InGaN) and GaN. The resulting superlattice may provide a high quality crystalline surface along the grooves for growth of subsequent layers.

After the surface preparation, a p-region 1010 may be formed on top of the flattening layer 1008. In some embodiments, the flattening layer 1008 may be planarized, e.g., using chemical-mechanical planarization (CMP), to produce a substantially planar growth surface for the p-region 1010. Alternatively, growth conditions of the flattening layer and/or the p-region may be controlled to make the flattening layer flat/flatter. The p-region 1010 can include a layer of Group III-V material (e.g., AlInP or GaP) that has been doped with a p-type dopant, e.g., with zinc (Zn) or magnesium (Mg) to form a p-AlInP layer. However, as with the n-region 1004, the p-region 1010 can be formed using a nitride-based Group III-V material.

The semiconductor structure 1000 can be further processed to form an LED. Additional processing steps may include, for example, depositing metal contacts (e.g., p-contacts and n-contacts). The additional processing may also include etching the semiconductor structure 1000 to form one or more LED mesas, where each LED mesa has an active region that includes one or more QW cells. In some embodiments, the semiconductor structure 1000 may include a sufficient number of QW cells 1034 to permit a two-dimensional array with a thousand or more LED mesas in each dimension (e.g., 1,500 mesas by 1,000 mesas or 2,000 mesas by 1,500 mesas) to be formed concurrently.

In the example of FIG. 10, the quantum wells are formed as part of creating the patterned template 1030 rather than being epitaxially grown onto a template that has been pre-patterned. One advantage to forming the quantum wells in this manner is that the geometry of the QW cells can potentially be formed more precisely, e.g., using an etch mask. However, it may be beneficial to have epitaxially grown QWs, since epitaxially grown QWs tend to have fewer surface defects compared to etched QWs (especially dry etched QWs), and therefore fewer opportunities for non-radiative recombination that would otherwise lead to reduced quantum efficiency.

FIG. 10 is merely one example of a semiconductor structure having etched quantum wells. Other embodiments may feature different process steps. For example, as discussed below, a semiconductor structure may be formed using a two-step etching process to define the mesas. The first etch step may produce an intermediate structure having a matrix of QW cells, similar to the patterned template 1030. During the second etch step, which can be performed after surface preparation as discussed above, the flattening layer 1008 may operate as a protective layer to prevent or minimize etch induced defects from forming along the mesa sidewalls. Therefore, the resulting semiconductor structure may have few surface defects at or near the mesa sidewalls even though the active region is etched as part of forming the intermediate structure.

Additionally, the technique shown in FIG. 10 can be performed without defining the grooves 1032 as precisely compared to other examples. In fact, the cross-sectional profile of the QW cells 1034 may be rectangular or some other shape as long as the QW cells have a sidewall angle (vertical or non-vertical). In some embodiments, the sidewall angle may be in the range of about 60 to 90 degrees (e.g., 80 degrees), where 90 degrees is fully vertical. The bottoms of the grooves 1032 do not have to form an exact “V” shape since no QW material is deposited onto the grooves 1032. In contrast, when QW material is grown over a ridge that has a substantially flat top or a groove that has a substantially flat bottom (e.g., in the case of epitaxially growing QWs over a patterned template), this could lead to reduced isolation between QW cells.

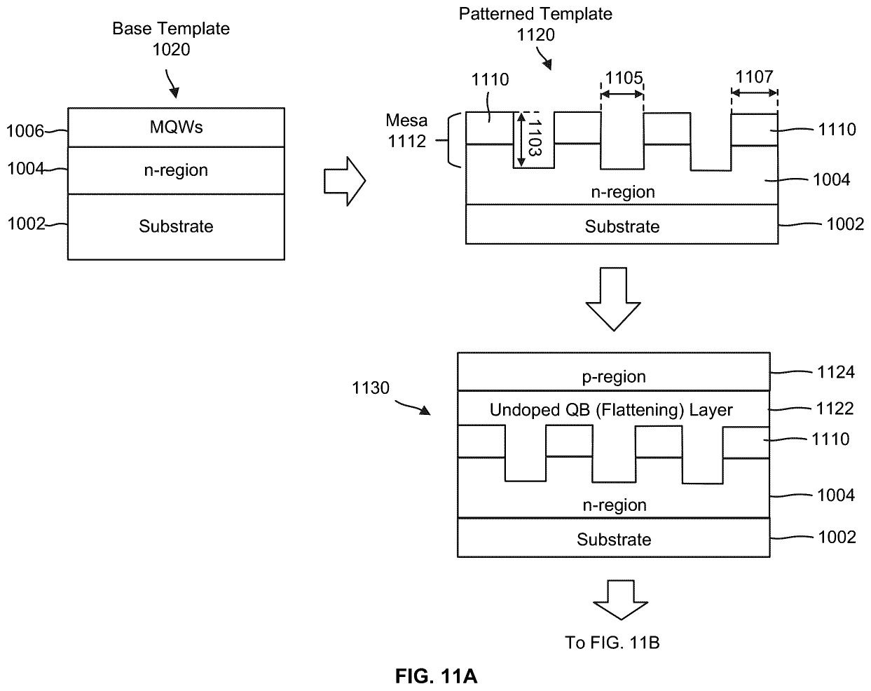

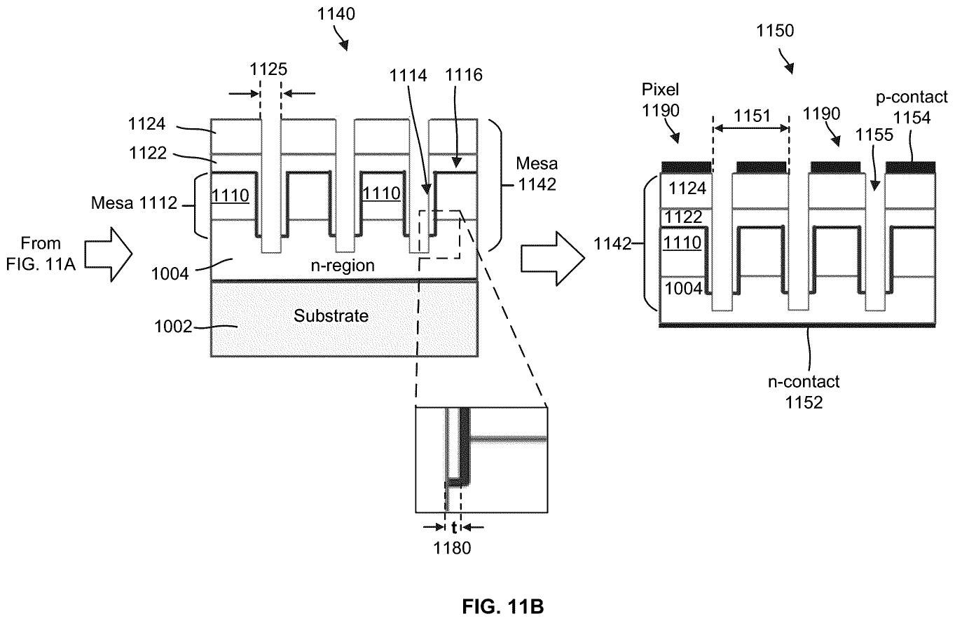

FIGS. 11A and 11B illustrate an example of a process for creating an LED device 1150 from a template, according to some embodiments. The process in FIGS. 11A and 11B involves forming a semiconductor structure similar to the semiconductor structure 400 in FIG. 4, with additional steps performed to produce the LED device 1150.

As shown in FIG. 11A, the process may begin with the base template 1020 described above in connection with FIG. 10. In this example, the base template 1020 is etched to form a patterned template 1120. As discussed above, various types of semiconductor materials may be used to form the base template through epitaxy, depending on the desired characteristics (e.g., emission color) of the LED being formed. For instance, in the case of a blue or green LED, the n-region 1004 of the base template 1020 may comprise a nitride-based Group III-V semiconductor material, e.g., n-doped GaN (n-GaN). As such, the quantum well material of the MQWs layer 1006 may also comprise a nitride, e.g., InGaN. Further, in some implementations, an n-doped superlattice (n-SL) may be formed on top of the n-region 1004 to provide a high quality crystalline surface for growth of the quantum wells and quantum barriers in the MQWs layer 1006.

The patterned template 1120 can be formed through dry etching and photolithography, using a patterned mask to define the areas of the base template 1020 that are etched. In this example, the base template 1020 is etched along vertical directions to define a matrix of cells 1110. Each cell 1110 corresponds to an individual mesa 1112 having substantially vertical sidewalls. Accordingly, each mesa 1112 may shaped like a 3D rectangle. However, as discussed above, other shape profiles are also possible. For instance, the mesas 1112 may be truncated pyramids. In general, the mesas 1112 can be any 3D shape characterized by a sidewall angle (e.g., 90 degrees in the case of a 3D rectangle), and a cross-sectional profile of the cells 1110 can be rectangular (as in FIG. 3) or some other shape, such as a hexagonal, circular, square, or some other 2D polygon.

Unlike the ridge or groove examples discussed above, the cells 1110 are spaced apart by gaps (e.g., trenches) corresponding to the areas etched away from the base template 1020. The etch depth defines a height 1103 of each mesa 1112. As shown, the gaps provide lateral separation along the entire height 1103, i.e., from the base of the mesa to the apex (top) of the mesa. The height 1103 can be nanoscale. For example, in some embodiments, the height 1103 may range from approximately 2 nm to approximately 500 nm. In the example shown, the base template 1020 is etched down into the n-region 1004 such that the base of each mesa 1112 includes a portion of the n-region. However, in some embodiments, the base template 1020 may be etched to a shallower depth so that the mesas extend from the MQWs layer 1006 (e.g., from the bottom-most quantum barrier layer). The lateral spacing between the mesas 1112 may correspond to an etch width 1105 of approximately 10 nm to approximately 2000 nm. The width 1107 of each mesa 1112 may range from approximately 100 nm to approximately 20,000 nm.

As discussed above in connection with the example semiconductor structures in FIG. 4, the mesa-shaped cells are QW cells where an individual QW cell may have one or more QW structures. The QW structures are quantum mechanically isolated by a quantum barrier, in this example, an undoped QB layer 1122. Depending on implementation, at least some of the cells 1110 may include two or more QW structures that correspond to sub-pixels, with each QW structure operating as a light emitter. The number of QW structures in each cell 1110 can be the same across all the cells. Alternatively, some cells 1110 may have more QW structures than other cells. The number of QW structures in each cell 1110 can be set based on the pattern of the etch mask used to form the patterned template 1120. In some embodiments, the QW structures within a cell may be arranged into a 2D array, such that the cell corresponds to a sub-matrix.

The patterned template 1120 is further processed through epitaxial overgrowth of the undoped QB layer 1122 and a p-region 1124 to form a semiconductor structure 1130 corresponding to the semiconductor structure 400 in FIG. 4. As discussed above, an undoped QB layer can be a flattening layer which, in some embodiments, has multiple layers. For instance, undoped QB layer 1122 may be the first layer grown over the patterned template 1120. One or more additional layers (not shown) may then be grown over the undoped QB layer (e.g., an n-EBL, a p-doped layer, an additional QB layer, etc.) to form the flattening layer of the semiconductor structure 1130.

The patterned template 1120 can be subjected to cleaning or some other surface preparation treatment before forming the undoped QB layer 1122 and the p-region 1124. For example, the patterned template 1120 may be subjected to ex-situ chemical wet-etch cleaning and/or in-situ thermo-chemical cleaning similar to the cleaning described above with respect to FIG. 10, in order to remove oxide and damage from the etched surfaces (e.g., the mesa sidewalls) of the cells 1110. In some embodiments, the patterned template 1120 may be thermally annealed in the presence of a suitable reactive chemical agent (e.g., ambient NH₃ gas or some other nitrogen gas in the case of a nitride-based active region, or phosphine gas in the case of a phosphide-based active region). Since the epitaxial layers grown on the substrate are relatively thin (e.g., based on the nanoscale dimensions mentioned above), the thermal annealing and/or other cleaning process may be sufficient to remove most of the defects induced by the etch that forms the patterned template 1120. For example, the MQWs layer 1006 may only be about 10 to 50 nm thick vertically, in which case thermal annealing alone may be sufficient. Additionally, wet-etch cleaning can be omitted in some instances. This is because the chemicals used for wet etching can damage exposed QW regions, creating new defects while at the same time removing defects leftover from the earlier etch.

FIG. 11B shows a semiconductor structure 1140 formed as a result of etching the semiconductor structure 1130. Like the etching used to form the patterned template 1120, the etching that produces the semiconductor structure 1130 can be a dry etch performed along a vertical direction. This second etch can be used to create larger mesas 1142 having sidewalls that extend along the p-region 1124, the undoped QB or flattening layer 1122 and, depending on etch depth, the n-region 1004. Each mesa 1142 corresponds to an individual pixel 1190 containing its own light emitting cell 1110. Accordingly, mesa pixelation may involve a two-step etch process in which the first etch is performed to create a matrix of cells from a base template (e.g., as part of forming the patterned template 1120), and the second etch defines the pixels that are ultimately incorporated into one or more LEDs. For instance, the second etch may define a pixel pitch 1151 (shown in the right side of FIG. 11B) of approximately 2 microns. The pixel pitch 1151 is the spacing between the pixels 1190, where each pixel 1190 corresponds to an individual mesa 1142 containing a respective cell 1110 along with respective portions of the p-region 1124 and n-region 1004.

The second etch is performed after forming the undoped QB/flattening layer 1122. As shown in FIG. 11B, the second etch cuts into the p-region 1124, the undoped QB layer 1122 and, optionally, into the n-region 1004. This is significant because the undoped QB layer 1122 can operate as a sacrificial layer that protects the cells 1110 from being exposed to the second etch. An etch width 1125 of the second etch can be narrower than the etch width 1105 used earlier to define the spacing between the cells 1110. As such, the second etch can form the larger mesas 1142 without creating additional surface defects on the sidewalls of the initial mesas 1112. This leaves a portion 1114 of the undoped QB layer 1122 as a thin layer covering the sidewalls of the initial mesas, with the sidewalls of the larger mesas 1142 extending along the undoped QB layer 1122.

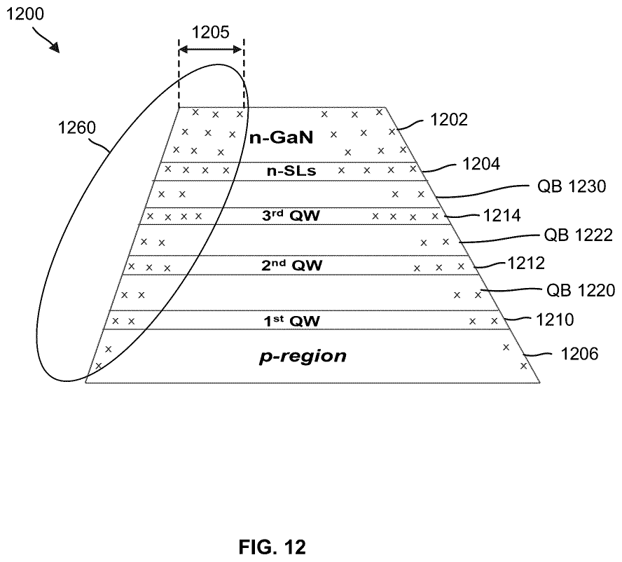

A lateral thickness 1180 of the portion 1114 may depend on the degree of protection to be provided by the undoped QB layer 1122. In particular, the lateral thickness 1180 can be set based on the depth of the etch-induced defects that would be expected had the cells 1110 been etched without first forming the undoped QB layer 1122. For instance, the lateral thickness 1180 can be set based on the depth 1205 shown in FIG. 12. The vertical thickness of the undoped QB layer 1122 is less important assuming that the undoped QB layer 1122 fully covers the sidewalls, e.g., as a continuous layer covering all the sidewall surfaces of each QW cell. As such, the portion 1114 can have a different (e.g., larger) thickness compared to a portion 1116 of the undoped QB layer 1122 covering the top surfaces of the mesas 1112. As one example, the thickness of the undoped QB layer 1122 on top of the QW cells can be less than 10 nm (e.g., around 5-6 nm) while the lateral thickness along the sidewalls of the QW cells can be greater than 10 nm (e.g., on the order of 100 nm). In general, making the top portion of the undoped QB layer 1122 thinner enables carriers to be injected more efficiently into the QWs.

In some embodiments, the lateral thickness of the undoped QB layer 1122 is sufficiently large such that the undoped QB layer 1122 occupies a majority of the width of each pixel 1190. In that case, the area of the active regions in the pixels, i.e., the QW cells, may be constrained so that the QW cells act as point sources of light (e.g., as Lambertian emitters), which would improve light extract efficiency.

FIG. 12 shows an example of dry-etch induced defects along the sidewalls of a mesa 1200. The mesa 1200 has sidewalls that span an n-region 1202, a superlattice region 1204, an active region, and a p-region 1206. In the example of FIG. 12, the positions of the n-region and the p-region are reversed relative to earlier examples.

The active region of the mesa 1200 may correspond to a QW cell 1110 in FIGS. 11A and 11B. Here, the active region is an MQW cell that includes a first QW layer 1210, a second QW layer 1212, and a third QW layer 1214. A first QB layer 1220 separates the QW layers 1210 and 1212. Similarly, a second QB layer 1222 separates the QW layers 1212 and 1214. The final (top-most) quantum barrier is a QB layer 1230 and can be replaced by the undoped QB layer 1122 or flattening layer discussed above, in order to prevent or reduce the etch-induced defects shown in this figure.

As shown in FIG. 12, etch-induced defects (marked with an “x”) along a sidewall area 1260 can vary in depth. This is because some materials are more susceptible to etch-induced defects than other materials. In particular, the QW layers 1210, 1212, and 1214 (e.g., InGaN quantum wells) are more prone to such defects, which tend to extend farther toward the center of the mesa 1200 in comparison to similar defects at or near the sidewall surfaces of the p-region 1206 and the QB layers 1220, 1222, 1230. For instance, InGaN quantum wells are highly vulnerable to the mechanical damage associated with dry etching as well as damage from wet chemical etching. This is because the bonding strength of a material generally decreases in correspondence with decreasing bandgap width. In the case of an active region, the material has to be low (narrow) bandgap in order to function as a quantum well.

The n-region 1202 and the superlattice region 1204 are also more susceptible to etch-induced defects. For example, like the quantum wells, the superlattice region 1204 may comprise InGaN. The n-region 1202 may be susceptible for reasons unrelated to its material composition. As shown in FIG. 12, the n-region 1202 may comprise n-GaN, which has a stronger bonding strength, and therefore resistance to etch damage, compared to InGaN. However, because the n-region 1202 is located at the top of the mesa 1200, the n-region 1202 is etched more aggressively due to being exposed to more of the etchant and for a longer duration compared to layers farther down. This is, of course, assuming that the etch is performed from the n-side of the mesa and not the p-side. Consequently, the n-region 1202 may be one of the areas where the defects extend the farthest into the mesa. However, the defects in the n-region 1202 and other areas outside the active region are less important from the perspective of quantum efficiency since such defects are not major contributors to non-radiative recombination. Instead, the centers of non-radiative recombination activity may correspond primarily to the locations of defects within the QW layers.

The etch-induced defects in FIG. 12 may include one or more types of Shockley-Read-Hall (SRH) recombination defects, such as vacancies (e.g., N, Ga), impurities (e.g., Cl, O), interstitials (e.g., Ga, In, Mg), dangling bonds, and/or point defect complexes. A depth 1205 of the defects may be measured in terms of lateral distance from the mesa sidewall. The depth 1205 typically ranges from approximately 3 nm to approximately 300 nm, e.g., 10 to 100 nm. Accordingly, in order to ensure sufficient protection against such defects, the thickness 1180 of the portion 1114 can be set at least equal to the depth 1205, in some cases even thicker.

The material of the undoped QB layer (e.g., GaN) is less prone to etch-induced defects since the undoped QB layer has a wider bandgap than the QW layers. As explained above, narrower bandgap correlates to weaker bonding strength and therefore susceptibility to etch damage. Moreover, the defects induced by the second etch (e.g., the etching that produces the semiconductor structure 1140) will be confined mainly to the undoped QB layer. Consequently, the sidewalls along the active region (e.g., the cells 1110) may not gain a significant number of new defects as a result of the second etch.

Another advantage of the mesa pixelation process described in connection with FIGS. 11A and 11B is that splitting the etching into two steps produces less damage and defects compared to using a single-step etch to create the resulting mesas. This is because each of the two etch steps can be performed using less extreme etch conditions, without etching as deeply, for as long a continuous duration, and/or as fast compared to a single step etch. In general, deeper etch depth, longer etch time, or faster etch rate leads to greater damage, e.g., a greater number of defects and/or defects that extend more deeply into the mesa.

Additionally, since the etch-induced defects produced by the first etch or primary mesa pixelation step (e.g., the etching that produces the patterned template 1120) can be reduced through surface preparation (e.g., thermal annealing), the total number of defects at or near the sidewall surfaces after the process in FIGS. 11A and 11B may be substantially less compared to conventional pixelation techniques such as mesa sidewall epitaxy (MSE). In MSE, the semiconductor structure is etched without first forming a protective layer. For example, MSE may involve forming the semiconductor structure complete with all its epitaxial layers (including a p-region and an n-region), then etching through the p-region, an active region, and into the n-region. After this etch, epitaxial regrowth may be performed to grow a layer on the mesa sidewalls by masking off the top surface of the mesas (e.g., the p-region) in addition to masking exposed portions of the n-region. However, the regrowth may not significantly reduce sidewall defects resulting from the etch.

Referring back to FIG. 11B, the semiconductor structure 1140 is processed to form an LED device 1150. The LED device 1150 is substantially complete and can function as a set of pixels for an LED display. However, further processing may be performed depending on the design of the LED display and also to connect the LED device 1150 to a driver circuit. Examples of such additional processing include forming a reflective coating over the mesa sidewalls to enhance light extraction, adding optical elements (e.g., collimating lenses) onto light-exit surfaces of the pixels, depositing a dielectric material to fill (at least partially) spaces 1155 between the mesas 1142, splitting a wafer containing multiple LED devices 1150 as part of creating a set of integrated circuit chips, bonding the wafer of LED devices to a wafer containing driver circuits, and/or other LED manufacturing steps.

As shown in FIG. 11B, the LED device 1150 includes an n-contact 1152 and separate p-contacts 1154 for each mesa 1142. The n-contact 1152 operates as a shared electrode for injection of electrons into the quantum wells of the cells 1110. In FIG. 11B, the n-contact 1152 is shown as being located on a side of the LED device 1150 opposite the p-contact 1154. Thus, the n-contact 1152 may be formed on a surface of the n-region 1004 that is exposed as a result of removing the substrate 1002. However, as shown in the example of FIG. 1, n-contacts and p-contacts can be on the same side depending on implementation. In some embodiments, instead of forming a single n-contact 1152 on the side of the n-region 1004 facing away from the p-region 1124, multiple n-contacts may be formed in the spaces between the pixels 1190. For example, n-contacts can be formed on the top surfaces of the n-region 1004 (facing toward the p-region 1124) that are exposed by second etch, where each n-contact is a shared electrode for two or more pixels 1190 that are adjacent to each other. Each p-contact 1154 can be connected to a separate signal line to individually drive the cells 1110. It is also possible to connect two or more p-contacts 1154 to the same signal line so that multiple cells 1110 are driven together.

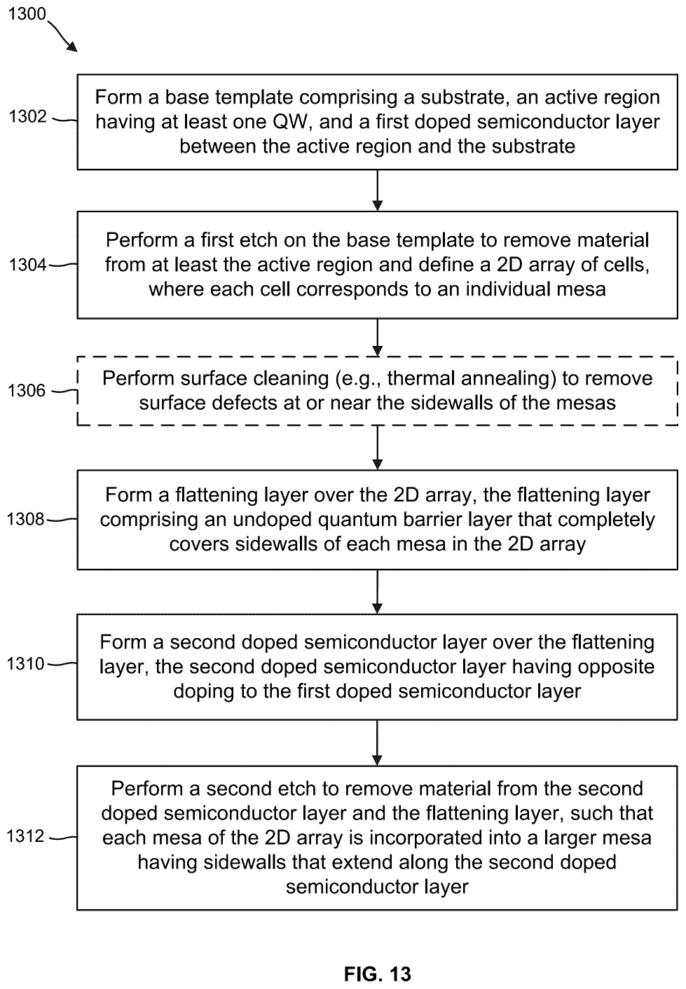

FIG. 13 is a flowchart of a method 1300 for forming an LED device, according to some embodiments. FIG. 13 is provided merely to illustrate certain steps that can be performed as part of forming an LED device. Additional processing may also be performed as part of the method 1300 including, for example, the processing described above in connection with forming the LED device 1150 in FIG. 11B.

The method 1300 begins at block 1302 with the formation of a base template, e.g., the base template 1020 in FIG. 11A. The base template is a semiconductor structure comprising a substrate, an active region, and a first doped semiconductor layer between the active region and the substrate. The active region includes at least one QW. In some instances, the active region includes multiple QWs, e.g., two or more layers of quantum well material separated by intervening layers of quantum barrier material. In general, the base template has a layered structure in which the layers are individually grown over the substrate using epitaxy, e.g., through metalorganic chemical vapor deposition (MOCVD).

The first doped semiconductor layer can be p-type or n-type and may comprise a Group III-V semiconductor. The quantum well(s) in the active region may also comprise a Group III-V semiconductor material. The semiconductor materials forming the first doped semiconductor layer, the active region, and the second doped semiconductor layer (in block 1310, discussed below) can be selected from a list of compatible semiconductors including, but not limited to, nitride-based or phosphide-based compounds. For example, a quantum well material can be a nitride (e.g., InGaN), and a material of the first doped semiconductor layer can be a nitride having chemical elements in common with the nitride of the quantum well material (e.g., GaN). Similarly, the quantum barrier material in the active region can also be a nitride, in some cases the same nitride as the first doped semiconductor layer (e.g., GaN).

At block 1304, a first etch is performed on the base template to remove material from at least the active region. The first etch may be a dry etch performed using photolithography. In some instances, the etch depth may extend into the first doped semiconductor layer. The first etch patterns the base template to define a 2D array of cells, where each cell corresponds to an individual mesa (e.g., the mesas 1112). Each cell corresponds to a light emitter since the cell includes a respective portion of the active region. Thus, the 2D array is formed as a matrix of QW cells.

At block 1306, surface cleaning may optionally be performed to remove surface defects at or near the sidewalls of the mesas in the 2D array. As discussed above, such cleaning may involve in-situ and/or ex-situ cleaning processes. In some implementations, the cleaning in block 1306 includes a thermal annealing step. The thermal annealing can be performed in-situ and in the presence of a suitable reactive chemical agent, e.g., NH₃ gas in the case of a nitride-based active region. The cleaning in block 1306 may at least partially recover from damage produced during the first etch in block 1304.

At block 1308, a flattening layer is formed over the 2D array. The flattening layer comprises an undoped QB layer and, optionally, one or more additional layers. The undoped QB layer or flattening layer can be epitaxially grown to completely cover the sidewalls of each mesa in the 2D array. As shown in the example of FIG. 11A, the undoped QB/flattening layer may also cover the top surfaces of the mesas. Based on FIG. 11A, it can be seen that the undoped QB/flattening layer can completely fill the spaces between the mesas, but such complete filling is optional. The flattening layer can be grown to be substantially flat through appropriate control of the growth conditions. Alternatively, as discussed above, the flattening layer may become flat or increase in flatness as a result of growing one or more additional layers over the flattening layer (e.g., the second doped semiconductor layer in block 1310).

At block 1310, the second doped semiconductor layer is formed over the flattening layer. The second doped semiconductor layer comprises a semiconductor material having an opposite doping relative to the first doped semiconductor layer. For example, the first doped semiconductor layer and the second doped semiconductor layer may comprise n-GaN and p-GaN, respectively.

At block 1312, a second etch is performed to remove material from the second doped semiconductor layer and the flattening layer. Like the first etch in block 1304, the second etch can be a dry etch. The second etch incorporates the mesas that were formed as a result of the first etch into larger mesas (e.g., mesas 1142 in FIG. 11B). The sidewalls of these larger mesas extend along the second doped semiconductor layer and the undoped QB/flattening layer. During the second etch, the undoped QB/flattening layer may operate to prevent the sidewalls of the initial mesas (e.g., mesas 1112) from being etched. As such, the undoped QB/flattening layer may act as a sacrificial layer that protects the cells against formation of additional defects at or near sidewall surfaces extending along the active region. The second etch can be designed to leave a portion of the undoped QB/flattening layer covering the sidewall surfaces of the initial mesas, as a thin protective layer that provides quantum mechanical isolation for the cells. As discussed above in connection with FIG. 12, the thickness of the portion left covering the sidewalls can be determined based on the expected depth of defects that would have been created in the absence of the flattening layer. In this way, any defects that are created as a result of the second etch may be confined to the portion covering the sidewalls.

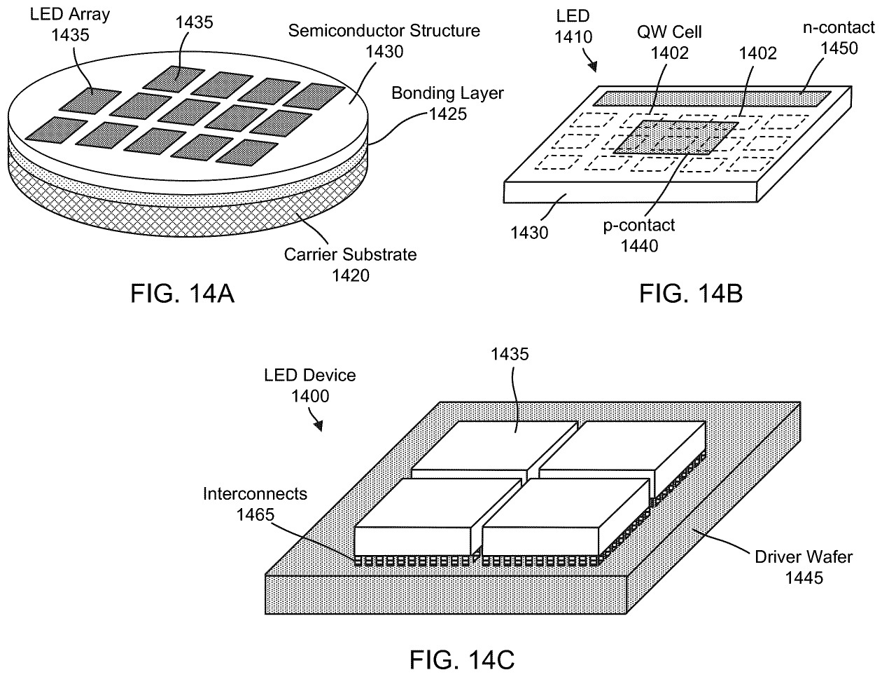

FIGS. 14A-14C illustrate an example of a process for forming an LED device 1400 according to certain embodiments. In FIG. 14A, multiple LED arrays 1435 are formed on a wafer comprising a semiconductor structure 1430, a bonding layer 1425, and a carrier substrate 1420. The semiconductor structure 1430 includes a plurality of semiconductor layers (not shown) and may, for example, correspond to a semiconductor structure featuring a matrix of QW cells as described in connection with any of the examples above. In some embodiments, the substrate on which the semiconductor structure 1430 is formed may be removed prior to adding the bonding layer 1425 and the carrier substrate 1420. The bonding layer 1425 may serve to temporarily attach the LED arrays 1435 to the carrier substrate 1420, with the carrier substrate 1420 holding the LED arrays 1435 in alignment so that the LED arrays 1435 can be bonded to a driver wafer 1445.

Each LED array 1435 may include a plurality of LEDs 1410. As shown in FIG. 14B, an LED 1410 in an LED array 1435 may include a QW matrix with multiple QW cells 1402. The area of the LED 1410 corresponding to the QW matrix may be etched to form an LED mesa (not shown) so that each LED array 1435 includes a separate mesa for each LED 1410. The LED 1410 may further include at least one p-contact 1440 and at least one n-contact 1450. The p-contact 1440 and the n-contact 1450 may be shared by the QW cells 1402. For example, the p-contact 1440 may be in ohmic contact with a p-doped region in the semiconductor structure 1430 and may be centered with respect to the QW matrix to overlap at least some of the QW cells 1402. The n-contact 1450 may be located around a perimeter of the LED 1410 and may be in ohmic contact with an n-doped region of the semiconductor structure 1430. The p-contact 1440 and the n-contact 1450 may be metallized contacts and can take various shapes. For example, the contacts 1440, 1450 may be planar contacts or bumped contacts having an interconnect material.

The LED arrays 1435 may be singulated through etching the semiconductor structure 1430, the bonding layer 1425, and the carrier substrate 1420 to separate the LED arrays 1435. As shown in FIG. 14C, the LED arrays 1435 may be bonded to the driver wafer 1445 after being singulated. The driver wafer 1445 may include one or more driver circuits that are embedded in a silicon substrate. The driver wafer 1445 may further include contacts corresponding to the contacts of the LED arrays 1435. The bonding of the LED arrays 1435 may involve inverting the LED arrays 1435 so that the contacts of the LED arrays 1435 (e.g., p-contact 1440 and n-contact 1450) are facing the contacts of the driver wafer 1445, then forming interconnects 1465, e.g., through metal-to-metal bonding of contact pads located on respective bonding surfaces of the driver wafer 1445 and the LED arrays.

The embodiments described herein may be used in conjunction with various technologies, such as an artificial reality system. An artificial reality system, such as a head-mounted display (HMD) or heads-up display (HUD) system, generally includes a display configured to present artificial images that depict objects in a virtual environment. The display may present virtual objects or combine images of real objects with virtual objects, as in virtual reality (VR), augmented reality (AR), or mixed reality (MR) applications. For example, in an AR system, a user may view both displayed images of virtual objects (e.g., computer-generated images (CGIs)) and the surrounding environment by, for example, seeing through transparent display glasses or lenses (often referred to as optical see-through) or viewing displayed images of the surrounding environment captured by a camera (often referred to as video see-through). In some AR systems, the artificial images may be presented to users using a light emitting diode (LED) based display subsystem.

In some embodiments, the systems, devices, and/or components (e.g., integrated circuits or integrated circuit packages) described herein may be integrated into an HMD. For example, such an HMD may include one or more light emitters and/or one or more light sensors incorporated into a portion of a frame of the HMD such that light can be emitted toward a tissue of a wearer of the HMD that is proximate to or touching the portion of the frame of the HMD. Example locations of such a portion of a frame of an HMD may include a portion configured to be proximate to an ear of the wearer (e.g., proximate to a superior tragus, proximate to a superior auricular, proximate to a posterior auricular, proximate to an inferior auricular, or the like), proximate to a forehead of the wearer, or the like. It should be noted that multiple sets of light emitters and light sensors may be incorporated into a frame of an HMD, e.g., such that a photoplethysmogram (PPG) can be determined from measurements associated with multiple body locations of a wearer of the HMD.

In the present description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

Embodiments disclosed herein may be used to implement components of an artificial reality system or may be implemented in conjunction with an artificial reality system. Artificial reality is a form of reality that has been adjusted in some manner before presentation to a user, which may include, for example, a virtual reality, an augmented reality, a mixed reality, a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including an HMD connected to a host computer system, a standalone HMD, a mobile device or computing system, or any other hardware platform capable of providing artificial reality content to one or more viewers.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments may be described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof. When implemented in software, firmware, middleware, or microcode, the program code or code segments to perform the associated tasks may be stored in a computer-readable medium such as a storage medium. Processors may perform the associated tasks.

It will be apparent to those skilled in the art that substantial variations may be made in accordance with specific requirements. For example, customized or special-purpose hardware might also be used, and/or particular elements might be implemented in hardware, software (including portable software, such as applets, etc.), or both. Further, connection to other computing devices such as network input/output devices may be employed.

With reference to the appended figures, components that can include memory can include non-transitory machine-readable media. The term “machine-readable medium” and “computer-readable medium” may refer to any storage medium that participates in providing data that causes a machine to operate in a specific fashion. In embodiments provided hereinabove, various machine-readable media might be involved in providing instructions/code to processing units and/or other device(s) for execution. Additionally or alternatively, the machine-readable media might be used to store and/or carry such instructions/code. In many implementations, a computer-readable medium is a physical and/or tangible storage medium. Such a medium may take many forms, including, but not limited to, non-volatile media, volatile media, and transmission media. Common forms of computer-readable media include, for example, magnetic and/or optical media such as compact disk (CD) or digital versatile disk (DVD), punch cards, paper tape, any other physical medium with patterns of holes, a RAM, a programmable read-only memory (PROM), an erasable programmable read-only memory (EPROM), a FLASH-EPROM, any other memory chip or cartridge, a carrier wave as described hereinafter, or any other medium from which a computer can read instructions and/or code. A computer program product may include code and/or machine-executable instructions that may represent a procedure, a function, a subprogram, a program, a routine, an application (App), a subroutine, a module, a software package, a class, or any combination of instructions, data structures, or program statements.

Those of skill in the art will appreciate that information and signals used to communicate the messages described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Terms, “and” and “or” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, AB, AC, BC, AA, ABC, AAB, AABBCCC, etc.

Further, while certain embodiments have been described using a particular combination of hardware and software, it should be recognized that other combinations of hardware and software are also possible. Certain embodiments may be implemented only in hardware, or only in software, or using combinations thereof. In one example, software may be implemented with a computer program product containing computer program code or instructions executable by one or more processors for performing any or all of the steps, operations, or processes described in this disclosure, where the computer program may be stored on a non-transitory computer readable medium. The various processes described herein can be implemented on the same processor or different processors in any combination.

Where devices, systems, components or modules are described as being configured to perform certain operations or functions, such configuration can be accomplished, for example, by designing electronic circuits to perform the operation, by programming programmable electronic circuits (such as microprocessors) to perform the operation such as by executing computer instructions or code, or processors or cores programmed to execute code or instructions stored on a non-transitory memory medium, or any combination thereof. Processes can communicate using a variety of techniques, including, but not limited to, conventional techniques for inter-process communications, and different pairs of processes may use different techniques, or the same pair of processes may use different techniques at different times.

The specification and drawings are, accordingly, to be regarded in an illustrative rather than a restrictive sense. It will, however, be evident that additions, subtractions, deletions, and other modifications and changes may be made thereunto. Thus, although specific embodiments have been described, these are not intended to be limiting. Various modifications and equivalents are within the scope of the following claims.

What is claimed is:

1. A light emitting diode (LED) device comprising:
a first doped semiconductor layer;
a second doped semiconductor layer having an opposite doping to the first doped semiconductor layer;
a two-dimensional (2D) array of pixels, each pixel corresponding to a three-dimensional mesa that contains a light emitting cell comprising at least one quantum well, wherein each light emitting cell is located between the first doped semiconductor layer and the second doped semiconductor layer; and
a flattening layer formed between the first doped semiconductor layer and each light emitting cell, wherein the flattening layer comprises an undoped quantum barrier layer that completely covers sidewalls of each light emitting cell.

2. The LED device of claim 1, wherein the undoped quantum barrier layer comprises a semiconductor material having a wider bandgap compared to a quantum well material of the light emitting cells.

3. The LED device of claim 1, wherein each light emitting cell comprises a plurality of quantum well layers separated by quantum barrier layers.

4. The LED device of claim 1, wherein the undoped quantum barrier layer completely covers a top surface of each light emitting cell, the top surface being a surface that faces the first doped semiconductor layer.

5. The LED device of claim 4, wherein a thickness of the undoped quantum barrier layer along a top surface of a light emitting cell is different from a thickness of the undoped quantum barrier layer along a sidewall of the light emitting cell.

6. The LED device of claim 5, wherein the thickness of the undoped quantum barrier layer along the top surface of the light emitting cell is smaller than the thickness of the undoped quantum barrier layer along the sidewall of the light emitting cell.

7. The LED device of claim 1, wherein a thickness of the undoped quantum barrier layer along the sidewalls of the light emitting cells ranges from approximately 3 nanometers to approximately 300 nanometers.

8. The LED device of claim 1, wherein the mesa of each pixel has sidewalls extending along the first doped semiconductor layer and the flattening layer.

9. The LED device of claim 1, further comprising:
an individual electrode formed on a surface of the first doped semiconductor layer in each pixel; and
a shared electrode formed on a surface of the second doped semiconductor layer.

10. The LED device of claim 1, wherein adjacent pixels are spaced apart by gaps corresponding to etched areas of the flattening layer.

11. The LED device of claim 10, wherein the gaps have a width ranging from approximately 10 nanometers to approximately 2,000 nanometers.

12. The LED device of claim 1, wherein the flattening layer further comprises one or more of:
an electron blocking layer;
a strain compensation layer;
a lightly-doped semiconductor layer; or
an additional quantum barrier layer.

13. The LED device of claim 1, wherein each light emitting cell has a sidewall angle in the range of 60 to 90 degrees, with 90 degrees being fully vertical.

14. The LED device of claim 1, wherein each light emitting cell has a height ranging from approximately 2 nanometers to approximately 500 nanometers.

15. The LED device of claim 1, wherein each light emitting cell has a width ranging from approximately 100 nanometers to approximately 20,000 nanometers.

16. A method for forming a light emitting diode (LED) device, the method comprising:
forming a base template comprising a substrate, an active region having at least one quantum well, and a first doped semiconductor layer between the active region and the substrate;
performing a first etch on the base template, wherein the first etch removes material from at least the active region to define a two-dimensional (2D) array of light emitting cells;
forming a flattening layer over the 2D array, wherein the flattening layer comprises an undoped quantum barrier layer that completely covers sidewalls of each light emitting cell in the 2D array;
forming a second doped semiconductor layer over the flattening layer, wherein the first doped semiconductor layer and the second doped semiconductor layer are oppositely doped; and
performing a second etch, wherein the second etch removes material from the second doped semiconductor layer and the flattening layer to incorporate each light emitting cell in the 2D array into a respective three-dimensional mesa corresponding to an individual pixel, the mesa having sidewalls that extend along the second doped semiconductor layer and the flattening layer.

17. The method of claim 16, wherein the second etch cuts into the undoped quantum barrier layer without removing material from the light emitting cells in the 2D array, and wherein the second etch leaves a portion of the undoped quantum barrier layer covering the sidewalls of each light emitting cell in the 2D array.

18. The method of claim 17, wherein the undoped quantum barrier layer operates to protect the light emitting cells in the 2D array against defects created as a result of the second etch, such that the defects do not extend beyond the portion of the undoped quantum barrier layer that is left covering the sidewalls of the light emitting cells in the 2D array.

19. The method of claim 16, further comprising:
removing the substrate; and
forming a single shared electrode on a surface of the first doped semiconductor layer that is exposed as a result of removing the substrate.

20. The method of claim 16, further comprising:
forming a plurality of shared electrodes, wherein each electrode in the plurality of shared electrodes is located between adjacent pixels and is formed on a surface of the first doped semiconductor layer exposed by the second etch.

21. The method of claim 16, further comprising:
performing thermal annealing before forming the flattening layer, wherein the thermal annealing removes defects located at or near the sidewalls of the light emitting cells in the 2D array, the defects being created as a result of the first etch.

22. The method of claim 21, wherein the thermal annealing is performed in-situ and in the presence of a reactive chemical gas agent.
